(19) United States
(12) Patent Application Publication
(10) Pub. No.: US 2026/0156827 A1
(43) Pub. Date: Jun. 4, 2026

(54) MEMORY DEVICE

(71) Applicant: Samsung Electronics Co., Ltd., Suwon-si (KR)

(72) Inventors: Seungmin SONG, Suwon-si (KR); Seogoo KANG, Suwon-si (KR); Kyungdong KIM, Suwon-si (KR); Kohji KANAMORI, Suwon-si (KR); Myunghoon HAN, Suwon-si (KR); Jeehoon HAN, Suwon-si (KR)

(73) Assignee: Samsung Electronics Co., Ltd., Suwon-si (KR)

(21) Appl. No.: 19/290,504

(22) Filed: Aug. 5, 2025

(30) Foreign Application Priority Data
Dec. 4, 2024 (KR) 10-2024-0178864

(51) Int. Cl. H10B 43/40; G11C 5/06; G11C 16/04; H01L 23/00; H01L 25/18; H10B 41/10; H10B 41/27; H10B 41/35; H10B 41/41; H10B 43/10; H10B 43/27; H10B 43/35; H10B 80/00; H10D 80/30

(52) U.S. Cl. CPC H10B 43/40; G11C 5/063; G11C 16/0483; H10B 41/10; H10B 41/27; H10B 41/35; H10B 41/41; H10B 43/10; H10B 43/27; H10B 43/35; H10B 80/00; H10D 80/30; H10W 90/00; H10W 90/20; H10W 90/732; H10W 90/734; H10W 90/792

(57) ABSTRACT

A memory device includes a peripheral circuit stack including circuits, a first gate stack on the peripheral circuit stack and including first gate lines stacked in a vertical direction, a first vertical channel structure penetrating the first gate stack, first gate line contacts penetrating the first gate stack, first dummy structures arranged adjacent to the first gate line contacts in a horizontal direction and penetrating the first gate stack, first through vias arranged apart from the first gate line contacts in the horizontal direction and connected to the circuits by penetrating the first gate stack, and a lower cell array stack including a first wiring structure that electrically connects the first through vias to the first gate line contacts. A distance between the first gate line contacts and the first through vias is greater than a distance between the first gate line contacts and the first dummy structures.

### CROSS-REFERENCE TO RELATED APPLICATION

This application is based on and claims priority under 35 U.S.C. § 119 to Korean Patent Application No. 10-2024-0178864, filed on Dec. 4, 2024, in the Korean Intellectual Property Office, the disclosure of which is incorporated by reference herein in its entirety.

### BACKGROUND

The inventive concepts relate to memory devices, and more particularly, to vertical memory devices including memory cells that are three-dimensionally arranged.

In electronic systems requiring data storage, there is an increasing demand for memory devices capable of storing high-capacity data. Accordingly, to increase data storage capacity of memory devices, a vertical memory device including three-dimensionally arranged memory cells has been suggested.

### SUMMARY

The inventive concepts provide memory devices that include three-dimensionally arranged memory cells and have improved integration and/or reliability.

Technical problems to be solved by the inventive concepts are not limited to the above description, and other technical problems may be clearly understood by one of ordinary skill in the art from the descriptions provided hereinafter.

According to an example embodiment of the inventive concepts, a memory device includes a peripheral circuit stack comprising a circuit substrate and a plurality of circuits thereon, a first gate stack on the peripheral circuit stack, the first gate stack comprising a plurality of first gate lines stacked in a vertical direction, a first vertical channel structure penetrating the first gate stack, a plurality of first gate line contacts penetrating at least a portion of the first gate stack, each of the plurality of first gate line contacts electrically connected to any one first gate line selected from among the plurality of first gate lines, a plurality of first dummy structures being adjacent to the plurality of first gate line contacts in a horizontal direction, the plurality of first dummy structures penetrating the first gate stack, a plurality of first through vias each being apart from a corresponding one of the plurality of first gate line contacts in the horizontal direction, the plurality of first through vias penetrating the first gate stack, each of the plurality of first through vias connected to any one of the plurality of circuits of the peripheral circuit stack, and a lower cell array stack comprising a first wiring structure that electrically connects at least any one of the plurality of first through vias to a corresponding one of the plurality of first gate line contacts, wherein a distance between a select one of the plurality of first gate line contacts and a corresponding one of the plurality of first through vias adjacent thereto in the horizontal direction is greater than a distance between the select one of the plurality of first gate line contacts and a corresponding one of the plurality of first dummy structures adjacent thereto in the horizontal direction.

According to an example embodiment of the inventive concepts, a memory device includes a peripheral circuit stack comprising a circuit substrate and a plurality of circuits thereon, a first gate stack on the peripheral circuit stack, the first gate stack comprising a plurality of first gate lines stacked in a vertical direction, a first vertical channel structure penetrating the first gate stack, a plurality of first gate line contacts penetrating at least a portion of the first gate stack, the plurality of first gate line contacts being apart from each other on the circuit substrate in a first horizontal direction and a second horizontal direction, the second horizontal direction being perpendicular to the first horizontal direction, each of the plurality of first gate line contacts electrically connected to any one first gate line selected from among the plurality of first gate lines, a plurality of first dummy structures adjacent to a periphery of the plurality of first gate line contacts, the plurality of first dummy structures spaced apart from each other in the first horizontal direction and the second horizontal direction, the plurality of first dummy structures penetrating the first gate stack, a plurality of first through vias each being apart from a corresponding one of the plurality of first gate line contacts adjacent thereto in a third horizontal direction, the third horizontal direction crossing the first horizontal direction and the second horizontal direction, the plurality of first through vias penetrating the first gate stack, each of the plurality of first through vias connected to any one of the plurality of circuits of the peripheral circuit stack by penetrating the first gate stack, and a lower cell array stack comprising a first wiring structure that electrically connects at least any one of the plurality of first through vias to a corresponding one of the plurality of first gate line contacts, wherein a distance between a select one of the plurality of first gate line contacts and one of the plurality of first through vias adjacent thereto in the horizontal direction is greater than a distance between the select one of the plurality of first gate line contacts and one of the plurality of first dummy structures adjacent thereto in the horizontal direction.

According to an example embodiment of the inventive concepts, a memory device includes a peripheral circuit stack comprising a circuit substrate and a plurality of circuits thereon, a lower cell array stack on the peripheral circuit stack, and an upper cell array stack on the lower cell array stack, wherein the lower cell array stack comprises a first gate stack on the peripheral circuit stack, the first gate stack comprising a plurality of first gate lines stacked in a vertical direction, a first vertical channel structure penetrating the first gate stack, a plurality of first gate line contacts each penetrating at least a portion of the first gate stack, a plurality of first dummy structures penetrating the first gate stack, each of the plurality of first dummy structures being adjacent to a corresponding one of the plurality of first gate line contacts adjacent thereto in a horizontal direction, a plurality of first through vias penetrating the first gate stack, each of the plurality of first through vias being apart from a corresponding one of the plurality of first gate line contacts adjacent thereto in the horizontal direction, each of the plurality of first through vias connected to any one of the plurality of circuits of the peripheral circuit, and a first wiring structure electrically connecting at least any one of the plurality of first through vias to a corresponding one of the plurality of first gate line contacts, a distance between a select one of the plurality of first gate line contacts and a corresponding one of the plurality of first through vias adjacent thereto in the horizontal direction is greater than a distance between the select one of the plurality of first gate line contacts and a corresponding one of the plurality of first dummy structures adjacent thereto in the horizontal direction, the upper cell array stack comprises a second gate stack comprising a plurality of second gate lines that are stacked in the vertical direction, a second vertical channel structure penetrating the second gate stack, a plurality of second gate line contacts each penetrating at least a portion of the second gate stack, a plurality of second dummy structures penetrating the second gate stack, each of the plurality of second dummy structures being adjacent to a corresponding one of the plurality o second gate line contacts adjacent thereto in the horizontal direction, a plurality of second through vias penetrating the second gate stack, each of the plurality of second through vias being spaced apart from a corresponding one of the plurality of second gate line contacts adjacent thereto in the horizontal direction, and a second wiring structure electrically connecting at least any one of the plurality of second through vias to a corresponding one of the plurality of second gate line contacts, and a distance between a select one of the plurality of second gate line contacts and a corresponding one of the plurality of second through vias adjacent thereto in the horizontal direction is greater than a distance between the select one of the plurality of second gate line contacts and a corresponding one of the plurality of second dummy structures adjacent thereto in the horizontal direction.

According to an example embodiment of the inventive concepts, a method of manufacturing a memory device includes forming a peripheral circuit stack comprising a circuit substrate and a plurality of circuits thereon, forming a first gate stack on the peripheral circuit stack, the first gate stack comprising a plurality of first gate lines stacked in a vertical direction, forming a first vertical channel structure to penetrate the first gate stack, forming a plurality of first gate line contacts to penetrate at least a portion of the first gate stack such that each of the plurality of first gate line contacts is electrically connected to any one first gate line selected from among the plurality of first gate lines, forming a plurality of first dummy structures to penetrate the first gate stack and to be adjacent to the plurality of first gate line contacts in a horizontal direction, forming a plurality of first through vias to penetrate the first gate stack and to be apart from a corresponding one of the plurality of first gate line contacts in the horizontal direction such that each of the plurality of first through vias is connected to any one of the plurality of circuits of the peripheral circuit stack, and forming a lower cell array stack including a first wiring structure such that the first wiring structure electrically connects at least any one of the plurality of first through vias to a corresponding one of the plurality of first gate line contacts, wherein a distance between a select one of the plurality of first gate line contacts and a corresponding one of the plurality of first through vias adjacent thereto in the horizontal direction is greater than a distance between the select one of the plurality of first gate line contacts and a corresponding one of the plurality of first dummy structures adjacent thereto in the horizontal direction.

The forming the plurality of first through vias may include arranging some of the plurality of first through vias to be adjacent to the plurality of first gate line contacts in the horizontal direction.

Each of the plurality of first dummy structures may comprise a first dummy insulating layer penetrating the first gate stack and each of the plurality of first through vias may include a first conductive plug and a first insulating liner surrounding sidewalls of the first conductive plug.

### BRIEF DESCRIPTION OF THE DRAWINGS

Example embodiments will be more clearly understood from the following detailed description taken in conjunction with the accompanying drawings in which:

FIG. 1 is a block diagram of a memory device according to an example embodiment;

FIG. 2 is a circuit diagram of a memory cell block according to an example embodiment;

FIG. 3A is a perspective view illustrating a representative structure of a memory device, according to an example embodiment;

FIG. 3B illustrates a memory device according to an example embodiment;

FIG. 4A is a planar layout of region “A” of FIG. 3A;

FIG. 4B is an example enlarged view of region “EX1” of FIG. 4A;

FIG. 5 is a cross-sectional view of the memory device, taken along a line A1-A1′ of FIG. 4A;

FIG. 6A is a cross-sectional view of the memory device, taken along a line A2-A2′ of FIG. 4A;

FIG. 6B is an enlarged view illustrating region “EX2” of FIG. 6A;

FIG. 7 is a cross-sectional view of the memory device, taken along a line A3-A3′ of FIG. 4A;

FIG. 8 is a cross-sectional view of the memory device, taken along a line B1-B1′ of FIG. 4A;

FIGS. 9 to 24 are cross-sectional views for explaining an example embodiment of a method of manufacturing a memory device;

FIG. 25 is a planar layout of a memory device according to an example embodiment;

FIG. 26 is a planar layout of a memory device according to an example embodiment;

FIG. 27A is a cross-sectional view of the memory device, taken along a line A2-A2′ of FIG. 26;

FIG. 27B illustrates a region corresponding to region “EX3” of FIG. 27A;

FIG. 28 schematically illustrates a data storage system including a memory device, according to an example embodiment;

FIG. 29 schematically illustrates a data storage system including a memory device, according to an example embodiment; and

FIG. 30 is a schematic cross-sectional view of a semiconductor package including a memory device, according to an example embodiment.

### DETAILED DESCRIPTION

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Hereinafter, one or more example embodiments of the inventive concepts will be described in detail with reference to the attached drawings. Like reference numerals in the drawings denote like elements, and repeated descriptions thereof will be omitted.

In the present specification, a horizontal direction may include a first horizontal direction (an X direction) and a second horizontal direction (a Y direction) that cross each other. The first horizontal direction (the X direction) may be a direction that is horizontal to the surfaces of both the first substrate and the second substrate, for example, the word line direction. The second horizontal direction (the Y direction) may refer to a direction that is horizontal to the surfaces of both the first substrate and the second substrate, for example, the bit line direction. The vertical direction (the Z direction) may refer to a direction perpendicular to the surfaces of both the first substrate and the second substrate, for example, a direction perpendicular to the word line and the bit line. In the present specification, the vertical level may be referred to as a height level of any structure along the vertical direction (the Z direction).

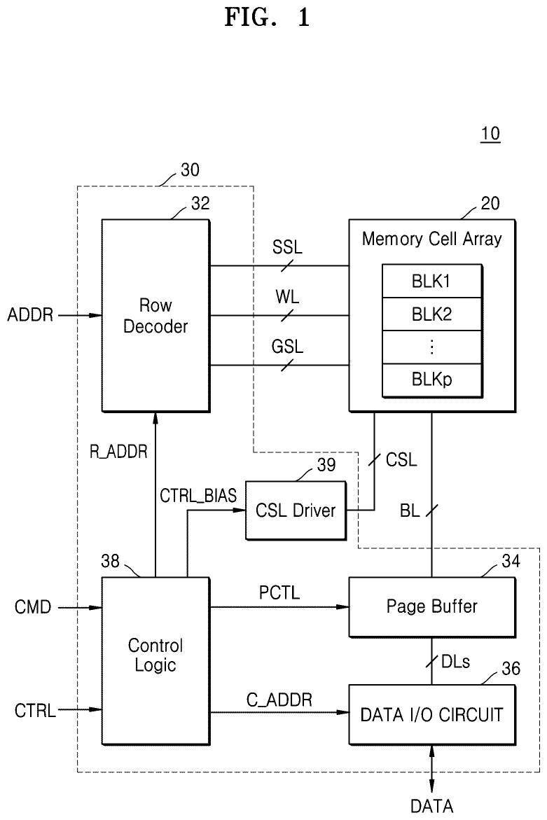

FIG. 1 is a block diagram of a memory device 10 according to an example embodiment.

Specifically, the memory device 10 may include a memory cell array 20 and a peripheral circuit 30. The memory cell array 20 includes a plurality of memory cell blocks BLK1, BLK2, . . . , and BLKn. The memory cell blocks BLK1, BLK2, . . . , and BLKn may each include a plurality of memory cells. The memory cell blocks BLK1, BLK2, . . . , and BLKn may be connected to the peripheral circuit 30 through a bit line BL, a word line WL, a string selection line SSL, and a ground selection line GSL.

The peripheral circuit 30 may include a row decoder 32, a page buffer 34, a data input/output circuit 36, a control logic 38, and a common source line driver 39. Although not shown in FIG. 1, the peripheral circuit 30 may further include an input/output interface, a column logic, a voltage generator, a pre-decoder, a temperature sensor, a command decoder, an address decoder, an amplifying circuit, and the like.

The memory cell array 20 may be connected to the page buffer 34 through the bit line BL and to the row decoder 32 through the word line WL, the string selection line SSL, and the ground selection line GSL. In the memory cell array 20, the memory cells in each of the memory cell blocks BLK1, BLK2, . . . , and BLKn may be flash memory cells. The memory cell array 20 may include a three-dimensional memory cell array. The three-dimensional memory cell array may include a plurality of NAND strings, and each NAND string may include a plurality of memory cells connected to a plurality of word lines WL that are vertically stacked on a substrate.

The peripheral circuit 30 may receive an address ADDR, a command CMD, and a control signal CTRL from the outside of the memory device 10 and may receive/transmit data DATA from/to a device outside the memory device 10.

The row decoder 32 may select at least one of the memory cell blocks BLK1, BLK2, . . . , and BLKn in response to an external address ADDR and select a word line WL, a string selection line SSL, and a ground selection line GSL of the selected memory cell block. The row decoder 32 may transmit a voltage used to perform a memory operation to the word line WL of the selected memory cell block.

The page buffer 34 may be connected to the memory cell array 20 through the bit line BL. The page buffer 34 may function as a write driver during a program operation and may apply, to the bit line BL, a voltage according to data DATA to be stored in the memory cell array 20, and the page buffer 34 may function as a sense amplifier during a read operation and may detect data DATA stored in the memory cell array 20. The page buffer 34 may operate according to a control signal PCTL provided from the control logic 38.

The data input/output circuit 36 may be connected to the page buffer 34 through data lines DLs. During the program operation, the data input/output circuit 36 may receive data DATA from a memory controller (not shown) and may provide program data DATA to the page buffer 34 based on a column address C_ADDR provided from the control logic 38. During the read operation, the data input/output circuit 36 may provide the memory controller with the read data DATA that is stored in the page buffer 34, based on the column address C_ADDR provided from the control logic 38.

The data input/output circuit 36 may transmit an input address or command to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and a column address C_ADDR to the data input/output circuit 36. The control logic 38 may generate a variety of internal control signals used in the memory device 10, in response to the control signal CTRL. For example, the control logic 38 may adjust a voltage level provided to the word line WL and the bit line BL during a memory operation, such as a program operation or an erase operation.

The common source line driver 39 may be connected to the memory cell array 20 through a common source line CSL. The common source line driver 39 may apply a common source voltage (e.g., a power voltage) or a ground voltage to the common source line CSL, according to a bias signal (CTRL_BIAS) by the control logic 38.

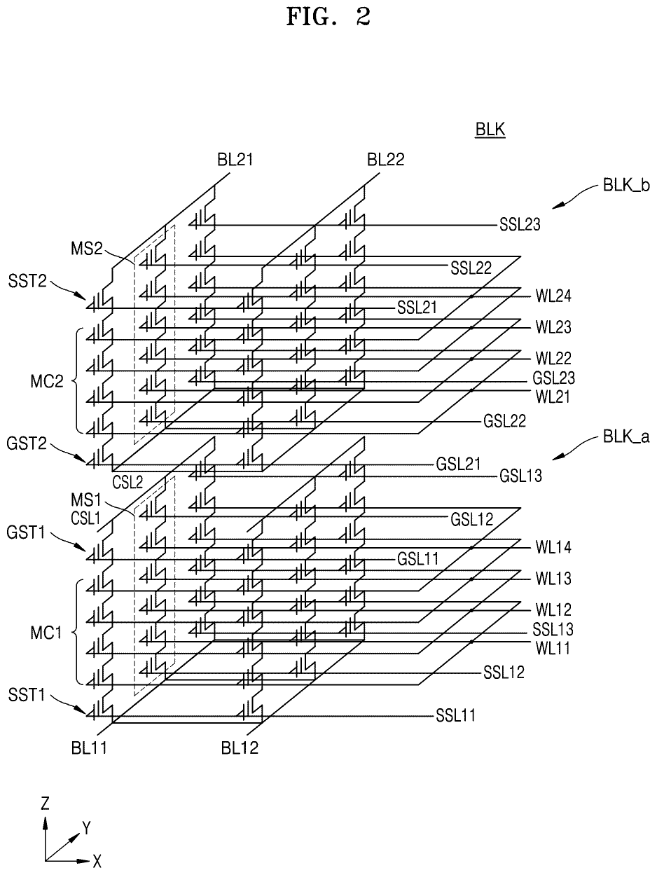

FIG. 2 is a circuit diagram of a memory cell block BLK according to an example embodiment.

For example, the memory cell block BLK may correspond to one of the memory cell blocks BLK1 to BLKn of FIG. 1. The memory cell block BLK may include a first sub-block BLK_a and a second sub-block BLK_b that are arranged at different vertical levels and vertically overlap each other. The first sub-block BLK_a may include first NAND strings MS1, and the second sub-block BLK_b may include second NAND strings MS2.

The first NAND string MS1 may include a first string selection transistor SST1, a plurality of first memory cells MC1, and a first ground selection transistor GST1, which are connected in series. The second NAND string MS2 may include a second string selection transistor SST2, a plurality of second memory cells MC2, and a second ground selection transistor GST2, which are connected in series. The first string selection transistor SST1, the first ground selection transistor GST1, and the first memory cells MC1 included in the first NAND string MS1 may form a vertical stack structure on a substrate, and the second string selection transistor SST2, the second ground selection transistor GST2, and the second memory cells MC2 included in the second NAND string MS2 may form a vertical stack structure on the substrate.

On the lower portion of the first NAND string MS1, first bit lines BL11 and BL12 may extend in a second horizontal direction (a Y direction), and first word lines WL11 to WL14 may extend in the a first horizontal direction (an X direction). The first NAND strings MS1 may be arranged between the first bit line BL1 and a first common source line CSL1. The first string selection transistor SST1 may be connected to corresponding first string selection lines SSL11 to SSL13. The first memory cells MC1 may be respectively connected to corresponding first word lines WL11 to WL14. The first ground selection transistor GST1 may be connected to corresponding first ground selection lines GSL11 to GSL13. The first string selection transistor SST1 may be connected to the corresponding bit line, and the first ground selection transistor GST1 may be connected to the first common source line CSL1.

On the upper portion of the second NAND string MS2, second bit lines BL21 and BL22 may extend in the second horizontal direction (the Y direction), and second word lines WL21 to WL24 may extend in the first horizontal direction (the X direction). The second NAND strings MS2 may be arranged between the second bit line BL2 and a second common source line CSL2. The second string selection transistor SST2 may be connected to corresponding second string selection lines SSL21 to SSL23. The second memory cells MC2 may be respectively connected to corresponding second word lines WL21 to WL24. The second ground selection transistor GST2 may be connected to corresponding second ground selection lines GSL21 to GSL23. The second string selection transistor SST2 may be connected to the corresponding bit line, and the second ground selection transistor GST2 may be connected to the second common source line CSL2.

Here, the number of NAND strings, the number of word lines, the number of bit lines, the number of ground selection lines, and the number of string selection lines may vary according to example embodiments.

In some example embodiments, the same voltage may be applied to each of the first word lines WL11 to WL14 and each of the second word lines WL21 to WL24 corresponding to the first word lines WL11 to WL14. For example, the lowermost first word line WL11 and the lowermost second word line WL21 may be electrically connected to a word line driving circuit (e.g., a pass transistor), and the same voltage may be applied thereto. Likewise, the uppermost first word line WL14 and the uppermost second word line WL24 may be electrically connected to a word line driving circuit (e.g., a pass transistor), and the same voltage may be applied thereto.

In some example embodiments, the same voltage may be applied to each of the first string selection lines SSL11 to SSL13 and each of the second string selection lines SSL21 to SSL23 corresponding to the first string selection lines SSL11 to SSL13, respectively. For example, the first string selection line SSL11 and the second string selection line SSL21 may be electrically connected to a string selection line driving circuit, and the same voltage may be applied thereto.

In some example embodiments, each of the first bit lines BL11 and BL12 may be configured to apply a voltage from a first page buffer circuit to the corresponding first NAND string MS1, and each of the second bit lines BL21 and BL22 may be configured to apply a voltage from a second page buffer circuit to the corresponding second NAND string MS2.

In some example embodiments, the same word line voltage may be applied to the first memory cell MC1, which is connected to the lowermost first word line WL11 in the first NAND string MS1, and the second memory cell MC2, which is connected to the lowermost second word line WL21 in the second NAND string MS2, and the bit line voltage applied to the first memory cell MC1 through the first bit line BL11 may be independent from the bit line voltage applied to the second memory cell MC2 through the second bit line BL21. Therefore, the first memory cell MC1 may be read, programmed, or erased independently of the second memory cell MC2. In some example embodiments, the bit line voltage applied to the first memory cell MC1 through the first bit line BL11 may also be applied to the second memory cell MC2 via arbitrary conductive components. The first memory cell MC1 may be read, programmed, or erased simultaneously with the second memory cell MC2.

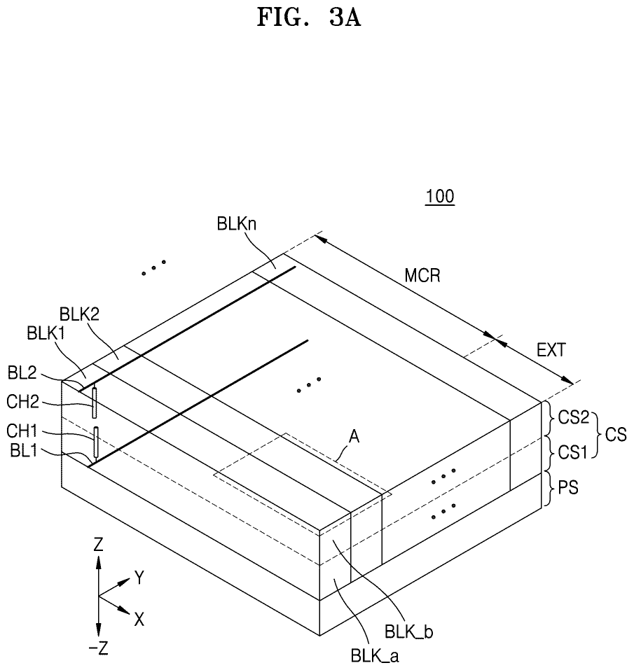

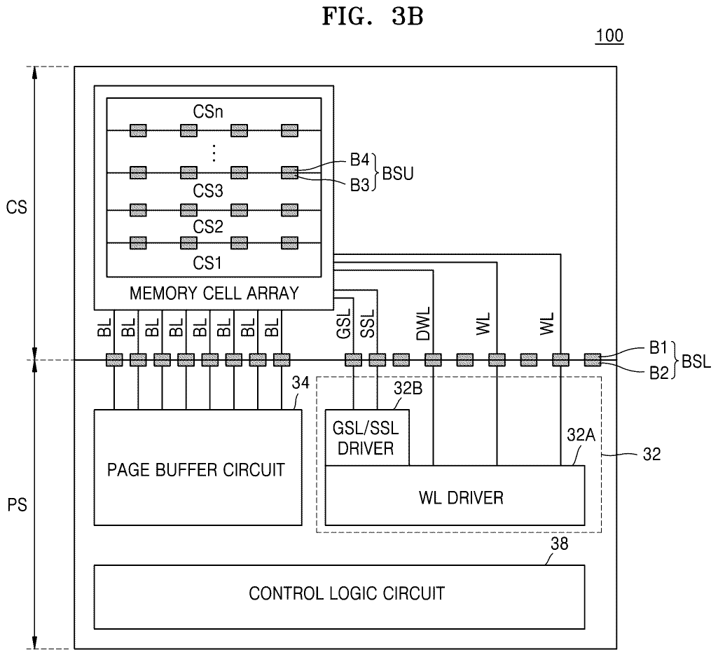

FIG. 3A is a perspective view illustrating a representative structure of a memory device 100, according to an example embodiment.

For example, the memory device 100 includes a cell array stack CS and a peripheral circuit stack PS that overlap each other in the vertical direction (the Z direction). The cell array stack CS may include the memory cell array 20 described with reference to FIG. 1, and the peripheral circuit stack PS may include the peripheral circuit 30 described with reference to FIG. 1.

The cell array stack CS may include a plurality of memory cell blocks BLK1 to BLKn. The memory cell blocks BLK1 to BLKn may each include memory cells that are three-dimensionally arranged. The memory cell blocks BLK1 to BLKn may each include a first sub-block BLK_a and a second sub-block BLK_b that overlap each other on the peripheral circuit stack PS in the vertical direction (the Z direction). The first sub-block BLK_a may include a first vertical channel structure CH1 and a first bit line BL1 connected to the first vertical channel structure CH1, and the second sub-block BLK_b may include a second vertical channel structure CH2 overlapping the first vertical channel structure CH1 and a second bit line BL2 connected to the second vertical channel structure CH2.

The cell array stack CS may include a memory cell region MCR and an extension region EXT, the memory cell region MCR may be a region including the memory cell array 20 described with reference to FIG. 1, and the extension region EXT may be a region in which electrical connection components for each word line WL of the memory cell array 20, for example, pad portions and/or contacts, are arranged.

In some example embodiments, the cell array stack CS may include a first cell array stack CS1 and a second cell array stack CS2 that overlap each other on the peripheral circuit stack PS. The first sub-block BLK_a may be arranged in the first cell array stack CS1, and the second sub-block BLK_b may be arranged in the second cell array stack CS2.

As shown in FIG. 3A, the first cell array stack CS1 may be arranged on the peripheral circuit stack PS, and the second cell array stack CS2 may be arranged on the first cell array stack CS1. In this case, in the first cell array stack CS1, the first bit line BL1 may be arranged on the peripheral circuit stack PS, and the first channel structure CH1 may be arranged on the first bit line BL1. In the second cell array stack CS2, the second channel structure CH2 may be arranged on the first cell array stack CS1, and the second bit line BL2 may be arranged on the second channel structure CH2.

FIG. 3B illustrates the memory device 100 according to an example embodiment.

For example, in FIG. 3B, the same reference symbols as in FIGS. 1 to 3A denote the same components, and detailed descriptions thereof are omitted. The memory device 100 may include the peripheral circuit stack PS and the cell array stack CS on the peripheral circuit stack PS. There may be a plurality of cell array stacks CS, and the memory device 100 may include cell array stacks CS1 to CSn. However, this is only an example, and the memory device 100 may include the first cell array stack CS1 and the second cell array stack CS2 shown in FIG. 3A. The cell array stack CS may include the memory cell array 20 described with reference to FIG. 1, and the peripheral circuit stack PS may include the peripheral circuit 30 described with reference to FIG. 1.

The cell array stacks CS1 to CSn may each include a plurality of bit lines BL, a ground selection line GSL, a string selection line SSL, a plurality of word lines WL, and a dummy word line DWL. The cell array stacks CS1 to CSn may each include a plurality of first bonding pads B1 that are connected to the plurality of bit lines BL, respectively, the ground selection line GSL, the string selection line SSL, the plurality of word lines WL, and the dummy word line DWL. The number of bit lines BL and the number of word lines WL connected to the cell array stacks CS1 to CSn may vary independently according to example embodiments, and the number of first bonding pads B1 in each of the cell array stacks CS1 to CSn may also vary according to example embodiments.

The peripheral circuit stack PS may include at least part of the row decoder 32, the page buffer 34, and the control logic 38 that are included in the peripheral circuit 30 described with reference to FIG. 1. The row decoder 32 may include a word line driver 32A and a ground selection line/string selection line driver 32B. The peripheral circuit stack PS may further include a voltage generator, an input/output circuit, and the like. The peripheral circuit stack PS may include a plurality of second bonding pads B2 arranged at positions corresponding to the first bonding pads B1. The bonding structure of the first bonding pad B1 and the second bonding pad B2 may form a lower bonding structure BSL.

Some of the second bonding pads B2 may be connected between the bit lines BL and the page buffer 34, other second bonding pads B2 may be connected between the word lines WL and the dummy word line DWL and the word line driver 32A, and the other second bonding pads B2 may be connected between the ground selection line GSL and the string selection line SSL and the ground selection line/string selection line driver 32B.

A plurality of bonding structures including a plurality of third bonding pads B3 and a plurality of fourth bonding pads B4 may be arranged between respective cell array stacks CS1 to CSn. The fourth bonding pads B4 may be arranged at positions corresponding to the third bonding pads B3. The bonding structure of the third bonding pad B3 and the fourth bonding pad B4 may form an upper bonding structure BSU.

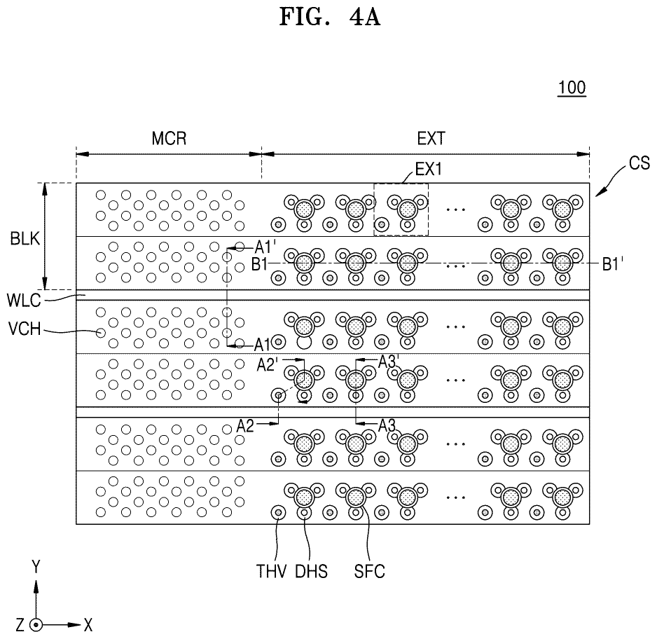

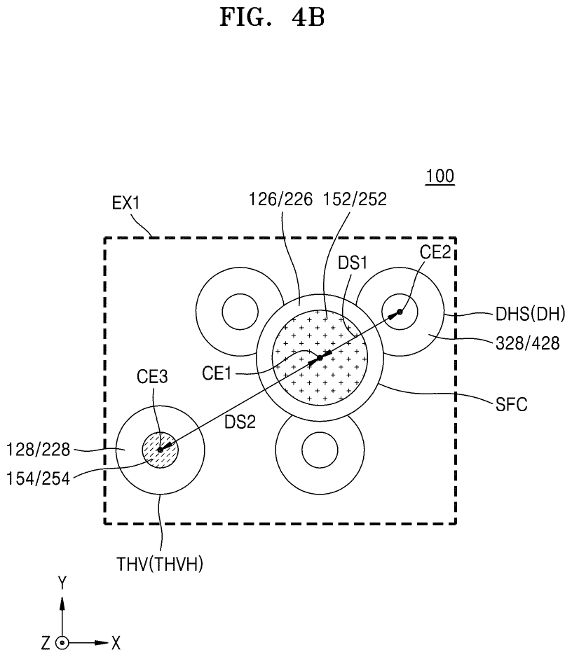

FIG. 4A is a planar layout of region “A” of FIG. 3A, and FIG. 4B is an example enlarged view of region “EX1” of FIG. 4A.

For example, the memory device 100 may include the peripheral circuit stack PS and a plurality of cell array stacks CS that are arranged on the peripheral circuit stack PS to overlap the same in the vertical direction (the Z direction). The cell array stacks CS may include the memory cell array 20 described with reference to FIG. 1, and the peripheral circuit stack PS may include the peripheral circuit 30 described with reference to FIG. 1.

The cell array stack CS may include a plurality of memory cell blocks BLK. The memory cell blocks BLK may correspond to the memory cell blocks BLK1, BLK2, . . . , and BLKn described with reference to FIG. 3A. Each memory cell block BLK may include a plurality of memory cells that are three-dimensionally arranged. Each memory cell block BLK may have a planar shape extending along the first horizontal direction (the X direction) in plan view (the X-Y plane in FIG. 4A). Each memory cell block BLK may include a memory cell region MCR and an extension region EXT arranged on a side of the memory cell region MCR in the first horizontal direction (the X direction).

A plurality of word line cut structures WLC, each extending from the memory cell region MCR and the extension region EXT in the first horizontal direction (the X direction), may be arranged between respective memory cell blocks BLK. The word line cut structures WLC may be arranged apart from each other in the second horizontal direction (the Y direction). The memory cell blocks BLK may be arranged between respective word line cut structures WLC. The word line cut structures WLC may be arranged on both sides of each memory cell block BLK in the second horizontal direction (the Y direction) to define the width of each memory cell block BLK in the second horizontal direction (the Y direction).

Each word line cut structure WLC may include an insulating structure. In some example embodiments, the insulating structure may include silicon oxide, silicon nitride, silicon oxynitride, or a low-k dielectric material. For example, the insulating structure may include a silicon oxide layer, a silicon nitride layer, an SiON layer, an SiOCN layer, an SiCN layer, or a combination thereof. In some example embodiments, at least a portion of the insulating structure may include an air gap. The term “air” used in the present specification may refer to the atmosphere or other gases present during the manufacturing processes.

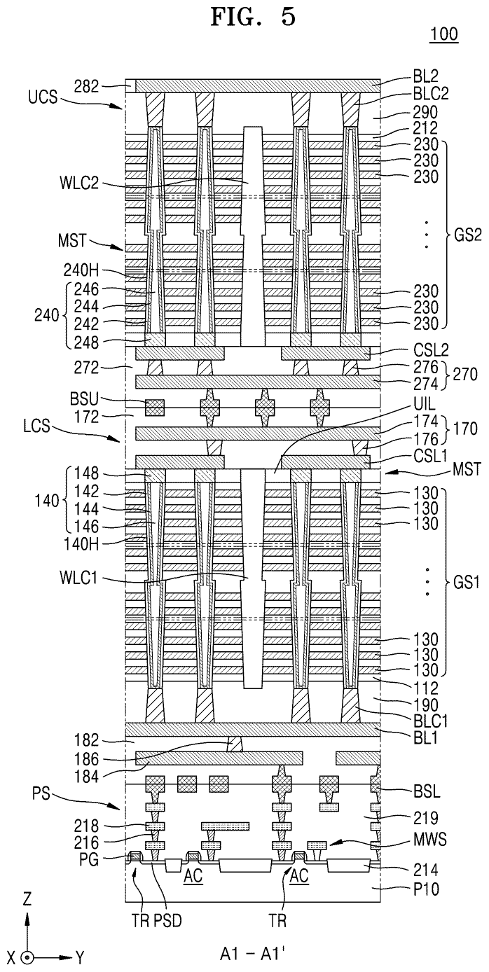

In addition, string selection isolation cut structures (not shown) may be arranged in one memory cell block BLK to form the first string selection lines (SSL11 to SSL13 of FIG. 2) and the second string selection lines (SSL21 to SSL23 of FIG. 2). The string selection isolation cut structure (not shown) may separate the gate lines (130 or 230 of FIG. 5) in the second horizontal direction (the Y direction) (e.g., the lowermost gate line and the uppermost gate line 130 or 230 of FIG. 5). The string selection isolation cut structure (not shown) may include an insulating layer. In some example embodiments, the string selection isolation cut structures may each include an insulating layer including an oxide layer, a nitride layer, or a combination thereof.

The memory cell block BLK may include the memory cell region MCR and the extension region EXT that is adjacent to the memory cell region MCR in the first horizontal direction (the X direction). In the memory cell block BLK, a plurality of vertical channel structures VCH may be arranged in the memory cell region MCR. In the extension region EXT, a plurality of gate line contacts SFC, a plurality of dummy structures DHS adjacent to the gate line contacts SFC, and a plurality of through vias THV spaced apart from the gate line contacts SFC may be arranged.

The gate line contacts SFC may be arranged apart from each other in the first horizontal direction (the X direction). The gate line contacts SFC may be arranged in a straight line (e.g., in a collinear fashion) in the first horizontal direction (the X direction) and the second horizontal direction (the Y direction). The gate line contacts SFC may include gate contact plugs 152/252 and gate insulating spacers 126/226 that surround side surfaces of the gate contact plugs 152/252.

Three dummy structures DHS may be arranged around each gate line contact SFC to surround the same. The dummy structure DHS may include dummy insulating layers 328/428 arranged in dummy holes DH. However, the number of dummy structures DHS that are adjacent to each gate line contact SFC is not limited to three as shown in the figure and may be one, two, or at least four.

The through via THV may be arranged apart from the gate line contact SFC in the horizontal direction (e.g., a third horizontal directing crossing the first horizontal direction (the X direction) and the second horizontal direction (the Y direction)). The through via THV may be arranged in a through hole THVH. The through via THV may include a conductive plug 154/254 and an insulating liner 128/228 that surrounds the conductive plug 154/254. In a limited sense, the through via THV may only refer to the conductive plug 154/254.

In some example embodiments, as shown in FIG. 4B, a second distance DS2 between the gate line contact SFC and the through via THV in the horizontal direction may be greater than a first distance DS1 between the gate line contact SFC and the dummy structure DHS in the horizontal direction. The second distance DS2 between the central point CE1 of the gate line contact SFC and the central point CE3 of the through via THV in the horizontal direction may be greater than the first distance DS1 between the central point CE1 of the gate line contact SFC and the central point CE2 of the dummy structure DHS in the horizontal direction.

In some example embodiments, the second distance DS2 may be twice the first distance DS1. In some example embodiments, the second distance DS2 may be in a range from about 600 nm to about 800 nm, and the first distance DS1 may be in a range from about 200 nm to about 400 nm.

As described, in the memory device 100, the through vias THV may be arranged apart from the gate line contacts SFC in the horizontal direction such that the generation of cracks between the gate line contacts SFC and the through vias THV may be restricted. Accordingly, in the memory device 100, three-dimensionally arranged memory cells are included to improve the integration, and crack formation is reduced or prevented, thereby enhancing reliability of the memory device 100.

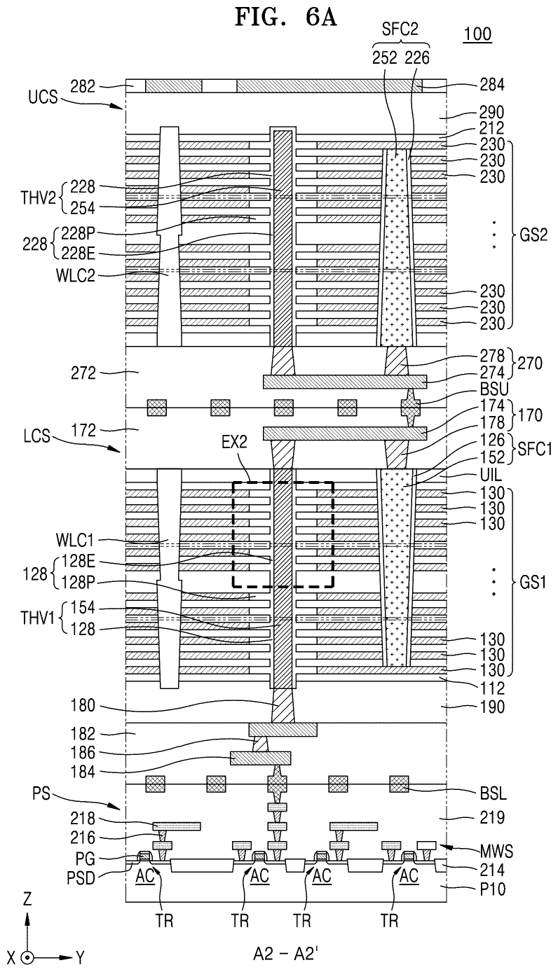

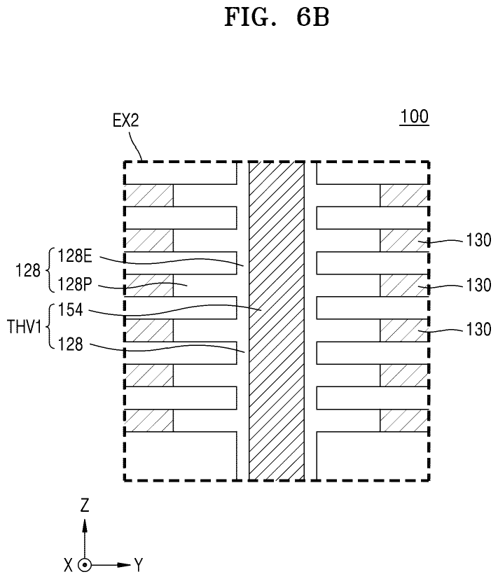

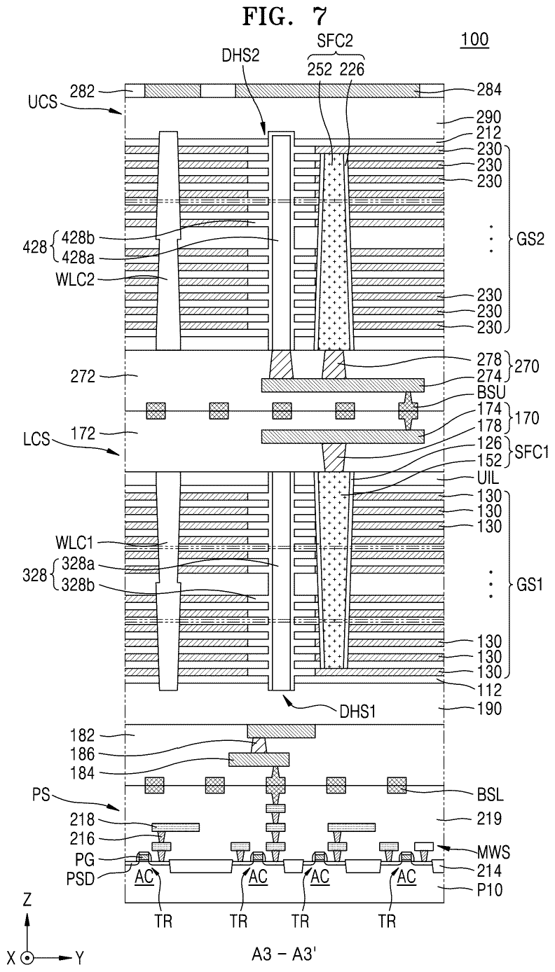

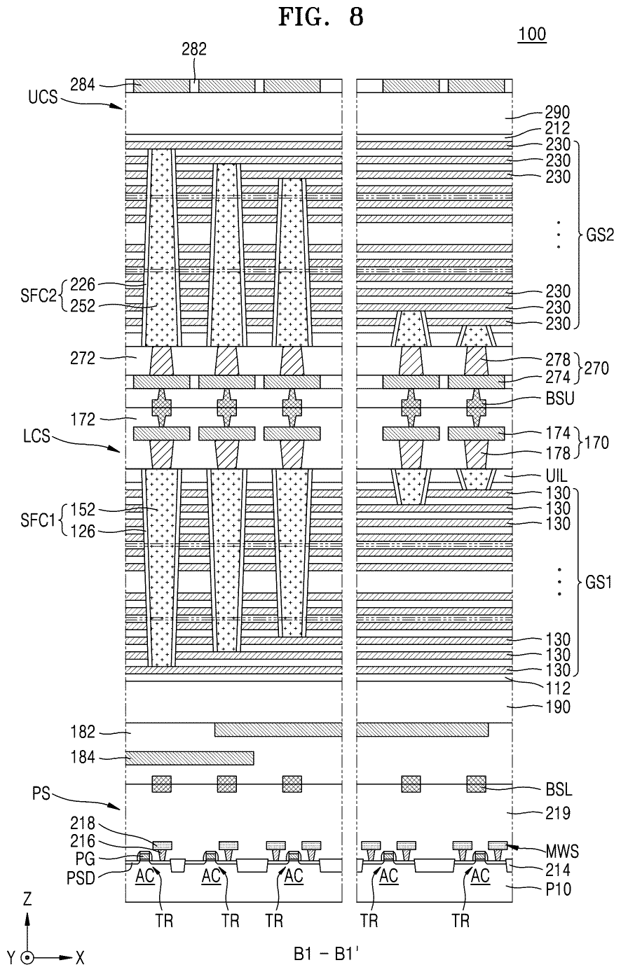

FIG. 5 is a cross-sectional view of the memory device 100, taken along a line A1-A1′ of FIG. 4A, FIG. 6A is a cross-sectional view of the memory device 100, taken along a line A2-A2′ of FIG. 4A, FIG. 6B is an enlarged view of region “EX2” of FIG. 6A, FIG. 7 is a cross-sectional view of the memory device 100, taken along a line A3-A3′ of FIG. 4A, and FIG. 8 is a cross-sectional view of the memory device 100, taken along a line B1-B1′ of FIG. 4A.

The structure of the memory device 100 is described for example with reference to FIGS. 5 to 8. In FIGS. 5 to 8, the same reference symbols as in FIGS. 1 to 3A denote the same components, and detailed descriptions thereof are omitted.

In the present specification, a cell array stack CS that is closest to the peripheral circuit stack PS among the cell array stacks CS may be referred to as a lower cell array stack LCS, and a cell array stack CS on the lower cell array stack LCS may be referred to as an upper cell array stack UCS. The upper cell array stack UCS may be spaced apart from the peripheral circuit stack PS in the vertical direction (the Z direction) with the lower cell array stack LCS therebetween.

In the present specification, referring to FIGS. 4A and 4B, the vertical channel structures VCH included in the lower cell array stack LCS among the vertical channel structures VCH may be referred to as first vertical channel structures 140, and the vertical channel structures VCH included in the upper cell array stack UCS may be referred to as second vertical channel structures 240. Among the word line cut structures WLC, the word line cut structures WLC included in the lower cell array stack LCS may be referred to as first word line cut structures WLC1, and the word line cut structures WLC included in the upper cell array stack UCS may be referred to as second word line cut structures WLC2.

Among the gate line contacts SFC, the gate line contacts SFC included in the lower cell array stack LCS may be referred to as first gate line contacts SFC1, and the gate line contacts SFC included in the upper cell array stack UCS may be referred to as second gate line contacts SFC2. Among the through vias THV, the through vias THV included in the lower cell array stack LCS may be referred to as first through vias THV1, and the through vias THV included in the upper cell array stack UCS may be referred to as second through vias THV2.

The peripheral circuit stack PS may include a circuit substrate P10, a plurality of circuits arranged on the circuit substrate P10, and a multilayer wiring structure MWS for interconnecting the circuits or connecting the circuits to components included in the cell array stacks CS.

In the peripheral circuit stack PS, the circuit substrate P10 may include a semiconductor substrate. For example, the circuit substrate P10 may include silicon (Si), germanium (Ge), or SiGe. Active regions AC may be defined in the circuit substrate P10 by a device isolation layer 214. Above the active regions AC, a plurality of transistors TR forming the circuits may be formed. Each of the transistors TR may include a gate PG and a plurality of ion implantation regions PSD formed on both sides of the gate PG in the active regions AC. Each ion implantation region PSD may form a source region or a drain region of the transistor TR.

The circuits included in the peripheral circuit stack PS may include various circuits included in the peripheral circuit 30 described with reference to FIG. 1. In some example embodiments, the circuits included in the peripheral circuit stack PS may include the row decoder 32, the page buffer 34, the data input/output circuit 36, the control logic 38, and the common source line driver 39 as shown in FIG. 1.

The multilayer wiring structure MWS included in the peripheral circuit stack PS may include a plurality of peripheral circuit contacts 216 and a plurality of circuit wiring layers 218. At least some of the circuit wiring layers 218 may be configured to be electrically connected to the transistors TR. The peripheral circuit contacts 216 may be configured to interconnect the transistors TR and selected ones of the circuit wiring layers 218.

A plurality of conductive components included in the lower cell array stack LCS and the upper cell array stack UCS may each be connected to at least one circuit selected from among the circuits through the multilayer wiring structure MWS included in the peripheral circuit stack PS. FIGS. 5, 6A, and 7 illustrate that the multilayer wiring structure MWS includes a tri-layer circuit wiring layer 218 in the vertical direction (the Z direction), but one or more example embodiments are not limited thereto. For example, the multilayer wiring structure MWS may include two or at least four circuit wiring layers 218.

The peripheral circuit contacts 216 and the circuit wiring layers 218 may each include metal, conductive metal nitride, metal silicide, or a combination thereof. For example, the peripheral circuit contacts 216 and the circuit wiring layers 218 may each include a conductive material, such as tungsten (W), molybdenum (Mo), titanium (Ti), cobalt (Co), tantalum (Ta), nickel (Ni), tungsten silicide, titanium silicide, cobalt silicide, tantalum silicide, or nickel silicide.

The transistors TR and the multilayer wiring structure MWS included in the peripheral circuit stack PS may be covered by a peripheral circuit insulating layer 219. The peripheral circuit insulating layer 219 may include silicon oxide, silicon oxynitride, silicon oxycarbonitride, or the like.

The lower cell array stack LCS may include a first insulating layer 190 on the peripheral circuit stack PS, a plurality of first gate insulating layers 112 and a plurality of first gate lines 130 that are alternately stacked on the first insulating layer 190 in the memory cell region (MCR of FIG. 4A), and a first common source line CSL1. The first gate lines 130 may form a first gate stack GS1.

The first common source line CSL1 may correspond to the first common source line CSL1 described with reference to FIG. 2. In other words, the first common source line CSL1 may function as a source region through which a current is supplied to vertical memory cells included in the lower cell array stack LCS. The first common source line CSL1 may be spaced apart from the upper surface of the first insulating layer 190 in the vertical direction (the Z direction) with the first gate stack GS1 on the first insulating layer 190 therebetween.

In some example embodiments, the first insulating layer 190 may include an insulating layer such as an oxide layer or a silicon oxide layer. The first common source line CSL1 may include a doped polysilicon layer, a metal layer, or a combination thereof. The metal layer may include W, but the material thereof is not limited thereto. Each of the first gate lines 130 may include metal, metal silicide, a semiconductor doped with impurities, or a combination thereof. For example, the first gate lines 130 may each include metal such as W, Ni, Co, or Ta, metal silicide such as tungsten silicide, nickel silicide, cobalt silicide, or tantalum silicide, doped polysilicon, or a combination thereof.

The first gate lines 130 may extend in parallel with each other in the horizontal direction (the X direction and the Y direction of FIG. 5) and overlap each other in the vertical direction (the Z direction). The first gate insulating layer 112 may be arranged between respective (or a corresponding pair of) first gate lines 130. In this case, the first gate insulating layer 112 may be arranged on an uppermost first gate line 130 among the first gate lines 130, and the first gate insulating layer 112 may be arranged on a lowermost first gate line 130 among the first gate lines 130. The first gate insulating layer 112 may include silicon oxide.

In the memory cell region (MCR of FIG. 4A), the first vertical channel structures 140 may be arranged on the first insulating layer 190. The first vertical channel structures 140 may penetrate the first gate lines 130 and the first gate insulating layers 112 and extend between the peripheral circuit stack PS and the first insulating layer 190 in the vertical direction (the Z direction). The first vertical channel structures 140 may be spaced apart from each other at certain intervals in the first horizontal direction (the X direction) and the second horizontal direction (the Y direction).

The first vertical channel structures 140 may each include a gate dielectric layer 142, a channel region 144, a buried insulating layer 146, and a capping layer 148. The first vertical channel structures 140 may each be a structure formed in a channel hole 140H penetrating the first gate stack GS1 and the first gate insulating layer 112. In an example embodiment, the gate dielectric layer 142 may conformally cover the sidewalls of the channel hole 140H, the channel region 144 may conformally cover the sidewalls of the gate dielectric layer 142 and the bottom of the channel hole 140H, and the buried insulating layer 146 may fill the remaining space in the channel hole 140H above the channel region 144.

In this case, the channel region 144 may have a cylinder shape. The capping layer 148 contacting the channel region 144 may be arranged on the gate dielectric layer 142, the channel region 144, and the buried insulating layer 146. In some example embodiments, the buried insulating layer 146 may be omitted, and the channel region 144 may be formed into a pillar shape that fills the remaining space of the channel hole 140H above the gate dielectric layer 142.

In some example embodiments, the gate dielectric layer 142 may include a tunneling dielectric layer, a charge storage layer, and a blocking dielectric layer that are sequentially formed. The tunneling dielectric layer may include silicon oxide, hafnium oxide, aluminum oxide, zirconium oxide, tantalum oxide, or the like. The charge storage layer may be a region in which electrons passing through the tunneling dielectric layer from the channel region 144 may be stored and may include silicon nitride, boron nitride, silicon boron nitride, or polysilicon doped with impurities. The blocking dielectric layer may include silicon oxide, silicon nitride, or metal oxide with permittivity greater than that of silicon oxide. The above metal oxide may include hafnium oxide, aluminum oxide, zirconium oxide, tantalum oxide, or a combination thereof.

In some example embodiments, the channel region 144 may include polysilicon doped with impurities or polysilicon not being doped with impurities. In some example embodiments, the buried insulating layer 146 may include silicon oxide, silicon nitride, silicon oxynitride, or a combination thereof. In some example embodiments, the capping layer 148 may include a doped polysilicon layer. The capping layers 148 may be insulated from each other by an upper insulating layer UIL.

The first vertical channel structures 140 are not limited to the structure illustratively shown in FIG. 5. For example, the structure in which the first vertical channel structures 140 are connected to the first common source line CSL1 may vary.

One end portion of the first vertical channel structures 140 may contact a first bit line contact BLC1 penetrating at least a portion of the first insulating layer 190, and the other end portion of the first vertical channel structures 140 may contact the first common source line CSL1.

In some example embodiments, the first bit line contact BLC1 and the first bit line BL1 may be arranged between the first vertical channel structures 140 and the peripheral circuit stack PS. The first vertical channel structures 140 may be electrically connected to the first bit line BL1 through the first bit line contact BLC1. A first lower wiring layer 184 and a first lower contact plug 186 may be arranged under the first bit line BL1.

The first bit line BL1 may be electrically connected to the first lower wiring layer 184 through the first lower contact plug 186 arranged between the first bit line BL1 and the first lower wiring layer 184. The surface of each of the first bit line BL1, the first lower wiring layer 184, and the first lower contact plug 186 may be covered by a first lower insulating layer 182.

In some example embodiments, the first common source lines CSL1 may be arranged apart from the peripheral circuit stack PS with the first vertical channel structures 140 therebetween. On the first common source lines CSL1, a first upper wiring layer 174 and a first upper contact plug 176 may be arranged.

The first common source lines CSL1 may be electrically connected to the first upper wiring layer 174 through the first upper contact plug 176 arranged between the first common source lines CSL1 and the first upper wiring layer 174. The surface of each of the first common source lines CSL1, the first upper wiring layer 174, and the first upper contact plug 176 may be covered by a first upper insulating layer 172.

The first word line cut structures WLC1 may be arranged adjacent to the first vertical channel structures 140 in the second horizontal direction (the Y direction). The first word line cut structures WLC1 may penetrate the first gate lines 130 and the first gate insulating layers 112 above the first insulating layer 190 and extend in the vertical direction (the Z direction). The first word line cut structures WLC1 may be arranged apart from each other at certain intervals in the second horizontal direction (the Y direction).

As shown in FIGS. 6A and 6B, first through vias THV1 may be arranged in the first insulating layer 190 in the extension region EXT. The first through vias THV1 may be spaced apart from the first word line cut structures WLC1 in the second horizontal direction (the Y direction). The first through via THV1 may penetrate the first gate lines 130 and the first gate insulating layers 112 above the first insulating layer 190 and extend in the vertical direction (the Z direction). In some example embodiments, the first through via THV1 may include a first conductive plug 154 and a first insulating liner 128 surrounding the sidewalls of the first conductive plug 154.

The first insulating liner 128 may include a first extension portion 128E extending along the sidewalls of the first conductive plug 154 and a plurality of first protrusions 128P protruding from the first extension portion 128E in the first horizontal direction (the X direction) and the second horizontal direction (the Y direction).

The first protrusions 128P may be aligned with the first gate lines 130 in the second horizontal direction (the Y direction). In addition, the first protrusions 128P may be aligned along the sidewalls of the first extension portion 128E and arranged apart from each other in the vertical direction (the Z direction) with the first gate insulating layer 112 therebetween. In some example embodiments, the first conductive plug 154 may include W, Ti, Ta, Cu, Al, TiN, TaN, WN, or a combination thereof, but the materials are not limited thereto. In some example embodiments, the first insulating liner 128 may include oxide or silicon oxide.

One end portion of the first through via THV1 may contact the first through contact 180 penetrating at least a portion of the first insulating layer 190, and the other end portion of the first through via THV1 may contact a first conductive stud 178.

In some example embodiments, a first through contact 180 may be arranged between the first through via THV1 and the peripheral circuit stack PS. In some example embodiments, the first through contact 180 may be omitted, and the first through via THV1 may extend such that one end portion of the first through via THV1 contacts the first lower wiring layer 184.

The first through via THV1 may be electrically connected to the first lower wiring layer 184 and thus electrically connected to any one peripheral circuit selected from among the peripheral circuits arranged on the peripheral circuit stack PS. For example, the peripheral circuit electrically connected to the first through via THV1 may include the row decoder (32 of FIG. 1) (e.g., a row decoder XDEC), and the first through via THV1 may be configured to receive a word line driving voltage or a pass voltage from the peripheral circuit.

In some example embodiments, a first wiring structure 170 may be arranged apart from the peripheral circuit stack PS with the first through via THV1 therebetween. The first wiring structure 170 may include a plurality of first conductive studs 178 and the first upper wiring layer 174 on the first conductive studs 178, and the surface of the first wiring structure 170 may be covered by the first upper insulating layer 172. The first conductive studs 178 may each be arranged on the upper surface of the first through via THV1 and the upper surface of the first gate line contact SFC1.

As shown in FIG. 8, the first gate line contacts SFC1 may be arranged on the first insulating layer 190 in the extension region EXT. The first gate line contacts SFC1 may penetrate the first gate lines 130 and the first gate insulating layers 112 above the first insulating layer 190 and extend in the vertical direction (the Z direction). The first gate line contacts SFC1 may be arranged apart from each other in the first horizontal direction (the X direction).

In this case, the first gate line contacts SFC1 may have different vertical lengths and may be physically and electrically connected to the first gate lines 130, respectively. In some example embodiments, the vertical lengths of the first gate line contacts SFC1 may shorten away from the memory cell region (MCR of FIG. 4A) in the first horizontal direction (the X direction), and the vertical level of the lower surfaces of the first gate line contacts SFC1 may increase away from the memory cell region (MCR of FIG. 4A) in the first horizontal direction (the X direction).

However, the first gate line contacts SFC1 are not limited to the arrangement in which the vertical lengths of the first gate line contacts SFC1 decrease away from the memory cell region (MCR of FIG. 4A) in the first horizontal direction (the X direction), and may be arranged in various shapes.

The first gate line contacts SFC1 may include a first gate contact plug 152 and a first gate insulating spacer 126 that surrounds the sidewalls of the first gate contact plug 152. In some example embodiments, the first gate contact plug 152 may include W, Ti, Ta, Cu, Al, TiN, TaN, WN, or a combination thereof, but the materials are not limited thereto. In some example embodiments, the first gate insulating spacer 126 may include oxide or silicon oxide.

As shown in FIG. 7, a first dummy structure DHS1 may be arranged adjacent to the first gate line contact SFC1. The first dummy structure DHS1 may include a first dummy insulating layer 328. The first dummy insulating layer 328 may include a first through insulating portion 328a penetrating the first gate stack GS1 and a first protruding insulating portion 328b protruding from the first through insulating portion 328a.

The first protruding insulating portion 328b may be a first peripheral insulating portion that surrounds the first through insulating portion 328a. The first through insulating portion 328a may include the same material as the first protruding insulating portion 328b. In some example embodiments, the first dummy insulating layer 328 may include silicon oxide, silicon nitride, silicon oxynitride, or a low-k dielectric material. The first dummy structure DHS1 may include an insulating material and may not be electrically connected to the first wiring structure 170.

As shown in FIGS. 6A and 8, the first through via THV1 and the first gate line contact SFC1 may be electrically connected to the first wiring structure 170. The first through via THV1 may be electrically connected, through the first wiring structure 170, to the first gate line contact SFC1 that is adjacent to the first through via THV1 among the first gate line contacts SFC1.

The first through via THV1 may be electrically connected to an adjacent first gate line contact SFC1 through the first wiring structure 170 and to the first gate line 130 that is electrically connected to the first gate line contact SFC1 among the first gate lines 130 of the lower cell array stack LCS.

The first through via THV1 may receive a word line driving voltage or a pass voltage from any one of the peripheral circuits of the peripheral circuit stack PS that is electrically connected to the first through via THV1 and may apply the word line driving voltage or the pass voltage to the first gate line 130 that is electrically connected to the first through via THV1. For example, the first through via THV1 may receive a pass voltage from the row decoder (32 of FIG. 1) (e.g., the row decoder XDEC) that is electrically connected to the first through via THV1 and may enable the first gate line 130 electrically connected to the first through via THV1.

The upper cell array stack UCS may have a structure that is substantially similar to that of the lower cell array stack LCS described above. The upper cell array stack UCS may overlap the peripheral circuit stack PS in the vertical direction (the Z direction) with the lower cell array stack LCS therebetween.

The upper cell array stack UCS may include a second insulating layer 290 on the lower cell array stack LCS, a plurality of second gate insulating layers 212 and a plurality of second gate lines 230 that are alternately stacked on the second insulating layer 290, and a second common source line CSL2. The second gate lines 230 may form a second gate stack GS2.

The second common source line CSL2 may correspond to the second common source line CSL2 described with reference to FIG. 2. In other words, the second common source line CSL2 may function as a source region through which a current is supplied to vertical memory cells included in the upper cell array stack UCS. The second common source line CSL2 may be spaced apart from the lower surface of the second insulating layer 290 in the vertical direction (the −Z direction) with the second gate stack GS2 on the second insulating layer 290 therebetween.

In some example embodiments, the second insulating layer 290 and the second common source line CSL2 may include materials that are similar to those of the first insulating layer 190 and the first common source line CSL1 described above, respectively.

In the memory cell region (MCR of FIG. 4A), the second vertical channel structures 240 may be arranged on the second insulating layer 290. The second vertical channel structures 240 may penetrate the second gate lines 230 and the second gate insulating layers 212 between the lower cell array stack LCS and the second insulating layer 290 and extend in the vertical direction (the Z direction).

The second vertical channel structures 240 may be spaced apart from each other at certain intervals in the first horizontal direction (the X direction) and the second horizontal direction (the Y direction). The second vertical channel structures 240 may be substantially similar to the first vertical channel structures 140, compared to the first vertical channel structures 140.

In other words, similar to the first vertical channel structures 140, the second vertical channel structures 240 may each include a gate dielectric layer 242, a channel region 244, a buried insulating layer 246, and a capping layer 248. However, the upper portions and the lower portions of the first vertical channel structures 140 may have shapes with horizontal widths decreasing downwards, while the upper portions and the lower portions of the second vertical channel structures 240 may have shapes with horizontal widths decreasing upwards.

Additionally, the capping layer 248 of the second vertical channel structures 240 may be at the lowest vertical level in the second vertical channel structures 240, and the capping layer 148 of the first vertical channel structures 140 may be at the highest vertical level in the first vertical channel structures 140.

The second vertical channel structures 240 are not limited to the structure illustratively shown in FIG. 5. For example, the structure in which the second vertical channel structures 240 are connected to the second common source line CSL2 may vary.

One end portion of the second vertical channel structures 240 may contact a second bit line contact BLC2 penetrating at least a portion of the second insulating layer 290, and the other end portion of the second vertical channel structures 240 may contact the second common source line CSL2.

In some example embodiments, the second bit line contact BLC2 and the second bit line BL2 may be spaced apart from the lower cell array stack LCS with the second vertical channel structures 240 therebetween. The second vertical channel structures 240 may be electrically connected to the second bit line BL2 through the second bit line contact BLC2. The surface of the second bit line BL2 may be covered by a second upper insulating layer 282.

In some example embodiments, the second common source lines CSL2 may be arranged between the second vertical channel structures 240 and the lower cell array stack LCS. A second lower wiring layer 274 and a second lower contact plug 276 may be arranged under the second common source lines CSL2. The second common source lines CSL2 may be electrically connected to the second lower wiring layer 274 through the second lower contact plug 276 arranged between the second common source lines CSL2 and the second lower wiring layer 274. The surface of each of the second common source lines CSL2, the second lower wiring layer 274, and the second lower contact plug 276 may be covered by a second lower insulating layer 272.

The second word line cut structures WLC2 may be arranged adjacent to the second vertical channel structures 240 in the second horizontal direction (the Y direction) of the second vertical channel structures 240. The second word line cut structures WLC2 may penetrate the second gate lines 230 and the second gate insulating layers 212 between the lower cell array stack LCS and the second insulating layer 290 and extend in the vertical direction (the Z direction).

As shown in FIG. 6A, second through vias THV2 may be arranged in the second insulating layer 290 in the extension region EXT. The second through vias THV2 may be spaced apart from the second word line cut structures WLC2 in the second horizontal direction (the Y direction). The second through via THV2 may penetrate the second gate lines 230 and the second gate insulating layers 212 on the second insulating layer 290 and extend in the vertical direction (the Z direction).

Similar to the first through via THV1, the second through via THV2 may include a second conductive plug 254 and a second insulating liner 228 that surrounds the sidewalls and upper surface of the second conductive plug 254. A portion of the second insulating liner 228 may be arranged between the second insulating layer 290 and the second conductive plug 254. The second insulating liner 228 may include a second extension portion 228E extending along the sidewalls of the second conductive plug 254 and a plurality of second protrusions 228P protruding from the second extension portion 228E in the horizontal direction (the X direction or the Y direction).

One end portion of the second through via THV2 may be surrounded by the second insulating layer 290, and the other end portion of the second through via THV2 may contact a second conductive stud 278. The one end portion of the second through via THV2 may be spaced apart from a second upper wiring layer 284 with a portion of the second insulating layer 290 therebetween.

In some example embodiments, a second wiring structure 270 may be arranged between the second through via THV2 and the lower cell array stack LCS. The second wiring structure 270 may include a plurality of second conductive studs 278 and a second lower wiring layer 274 on the second conductive studs 278, and the surface of the second wiring structure 270 may be covered by the second lower insulating layer 272. The second conductive studs 278 may be arranged on the lower surface of the second through via THV2 and the lower surface of the second gate line contact SFC2, respectively.

As shown in FIG. 8, the second gate line contacts SFC2 may be arranged on the second insulating layer 290 in the extension region EXT. The second gate line contacts SFC2 may penetrate the second gate lines 230 and the second gate insulating layers 212 and extend in the vertical direction (the Z direction).

In this case, the second gate line contacts SFC2 may have different vertical lengths and may be physically and electrically connected to the second gate lines 230, respectively. In some example embodiments, the second gate line contacts SFC2 may be spaced apart from each other in the first horizontal direction (the X direction) and may have vertical lengths decreasing away from the memory cell region (MCR of FIG. 4) in the second horizontal direction (the Y direction).

The vertical level of the upper surfaces of the second gate line contacts SFC2 may decrease away from the memory cell region (MCR of FIG. 4A) in the first horizontal direction (the X direction). However, the second gate line contacts SFC2 are not limited to the arrangement in which the vertical lengths decrease away from the memory cell region (MCR of FIG. 4A) in the first horizontal direction (the X direction) and may be arranged in various shapes.

In some example embodiments, any selected one of the first gate line contacts SFC1 may have the same vertical length as the second gate line contact SFC electrically connected to the selected first gate line contact SFC1.

In other words, when any selected one of the first gate line contacts SFC1 is in contact with any selected one of the first gate lines 130, the second gate line contact SFC2 electrically connected to the selected first gate line contact SFC1 may contact the second gate line 230 corresponding to the second gate line contact SFC2.

For example, when any selected one of the first gate line contacts SFC1 is in contact with the lowermost first gate line 130, the second gate line contact SFC2 electrically connected to the selected first gate line contact SFC1 may be in contact with the uppermost second gate line 230.

Similar to the first gate line contacts SFC1, the second gate line contacts SFC2 may each include the second gate contact plug 252 and the second gate insulating spacer 226 that surrounds the sidewalls of the second gate contact plug 252. However, the first gate line contacts SFC1 may have shapes with horizontal widths decreasing downwards, while the second gate line contacts SFC2 may have shapes with horizontal widths decreasing upwards.

As shown in FIG. 7, a second dummy structure DHS2 may be arranged adjacent to the second gate line contact SFC2. The second dummy structure DHS2 may include a second dummy insulating layer 428. The second dummy insulating layer 428 may include a second through insulating portion 428a penetrating the second gate stack GS2 and a second protruding insulating portion 428b protruding from the second through insulating portion 428a.

The second protruding insulating portion 428b may be a second peripheral insulating portion that surrounds the second through insulating portion 428a. The second through insulating portion 428a may include the same material as the second protruding insulating portion 428b. In some example embodiments, the second dummy insulating layer 428 may include silicon oxide, silicon nitride, silicon oxynitride, or a low-k dielectric material. The second dummy structure DHS2 may include an insulating material and may not be electrically connected to the first wiring structure 170.

As shown in FIGS. 6A and 8, the second through via THV2 and the second gate line contact SFC2 may be electrically connected to the second wiring structure 270. The second through via THV2 may be electrically connected, through the second wiring structure 270, to the second gate line contact SFC2 that is adjacent to the second through via THV2 among the second gate line contacts SFC2.

As described above, the first through via THV1 may be electrically connected to an adjacent first gate line contact SFC1 and to the first gate line 130 that is electrically connected to the first gate line contact SFC1 among the first gate lines 130 of the lower cell array stack LCS.

In addition, the first through via THV1 may be electrically connected to an adjacent second gate line contact SFC2 through the first wiring structure 170, the upper bonding structure BSU, and the second wiring structure 270 and may be electrically connected to the second gate line 230 that is electrically connected to the second gate line contact SFC2 among the second gate lines 230 of the upper cell array stack UCS.

The first through via THV1 may receive a word line driving voltage or a pass voltage from any one of the peripheral circuits of the peripheral circuit stack PS that is electrically connected to the first through via THV1 and may apply the word line driving voltage or the pass voltage to the first gate line 130 of the lower cell array stack LCS, which is electrically connected to the first through via THV1, and the second gate line 230 of the upper cell array stack UCS, which is electrically connected to the first through via THV1.

For example, the first through via THV1 may receive a pass voltage from the row decoder (32 of FIG. 1) (e.g., the row decoder XDEC) that is electrically connected to the first through via THV1 and may enable the first gate line 130 of the lower cell array stack LCS electrically connected to the first through via THV1 and the second gate line 230 of the upper cell array stack UCS electrically connected to the first through via THV1.

The lower bonding structures BSL may be arranged between the first lower wiring layer 184 of the lower cell array stack LCS and the peripheral circuit stack PS, and the upper bonding structures BSU may be arranged between the lower cell array stack LCS and the upper cell array stack UCS.

The lower bonding structures BSL may each include a pair including a first bonding metal pad included in the lower cell array stack LCS and a second bonding metal pad included in the peripheral circuit stack PS. The upper bonding structures BSU may each include a pair including a first bonding metal pad included in the upper cell array stack UCS and a second bonding metal pad included in the lower cell array stack LCS.

The first bonding metal pad and the second bonding metal pad may each include Cu, Al, or W, but one or more example embodiments are not limited thereto. The first bonding metal pad and the second bonding metal pad may be integrally coupled.

The second bit line BL2 included in the upper cell array stack UCS may be connected to the page buffer 34 (see FIGS. 1 and 3B) through conductive structures included in the upper cell array stack UCS under the second bit line BL2, the upper bonding structure BSU, conductive structures included in the lower cell array stack LCS, and the lower bonding structure BSL.

In the memory device 100 of an example embodiment, the first dummy structures DHS1 and the second dummy structures DHS2 may be arranged adjacent to the first gate line contacts SFC1 and the second gate line contacts SFC2, and the first through vias THV1 and the second through vias THV2 may be arranged apart from the first gate line contacts SFC1 and the second gate line contacts SFC2, respectively.

According to the example embodiment, the reliability of the memory device 100 may be improved by reducing or preventing the formation of cracks between the first through vias THV1 and the second through vias THV2 that are spaced apart from the first gate line contacts SFC1 and the second gate line contacts SFC2, respectively.

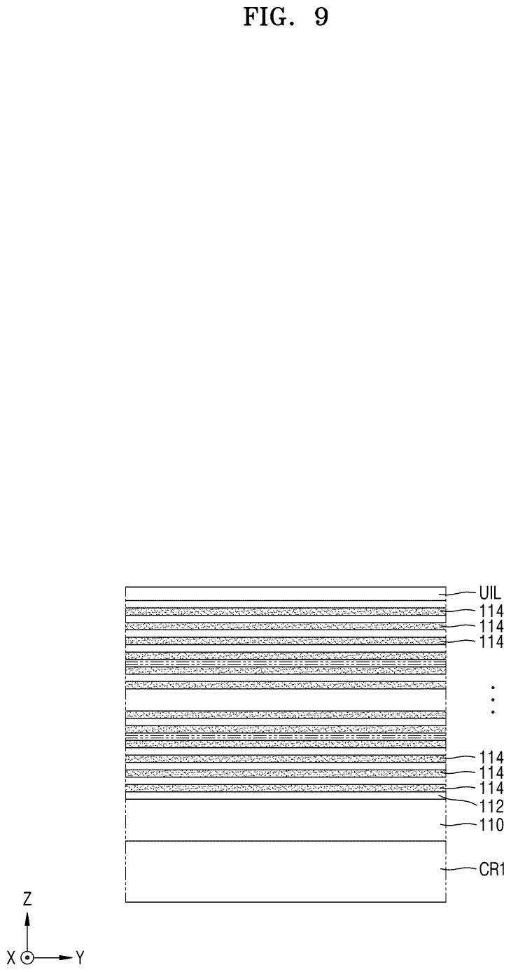

FIGS. 9 to 24 are cross-sectional views for explaining an example embodiment of a method of manufacturing a memory device.

For example, referring to FIGS. 9 to 24, an example method of manufacturing the memory device 100 described above with reference to FIGS. 4A to 8 is described.

In FIGS. 9 to 24, the same reference numerals as in FIGS. 4A to 8 denote the same components, and detailed descriptions thereof are omitted. FIGS. 9 to 24 illustrate cross-sections taken along a line A2-A2′ of FIG. 4A.

Referring to FIG. 9, in the extension region EXT, a first substrate 110 may be formed on a first carrier substrate CR1, and a stack structure in which a plurality of first gate insulating layers 112 and a plurality of sacrificial insulating layers 114 are alternately stacked may be formed on the first substrate 110. For example, the first gate insulating layers 112 may each include a silicon oxide layer, and the sacrificial insulating layers 114 may each include a silicon nitride layer.

The sacrificial insulating layers 114 may each be configured to secure a space for forming the gate lines (130 of FIG. 6A) in a subsequent process. The first gate insulating layers 112 may be positioned on the lowermost portion and the uppermost portion of the above stack structure. Then, the upper insulating layer UIL covering the upper surface of the stack structure may be formed.

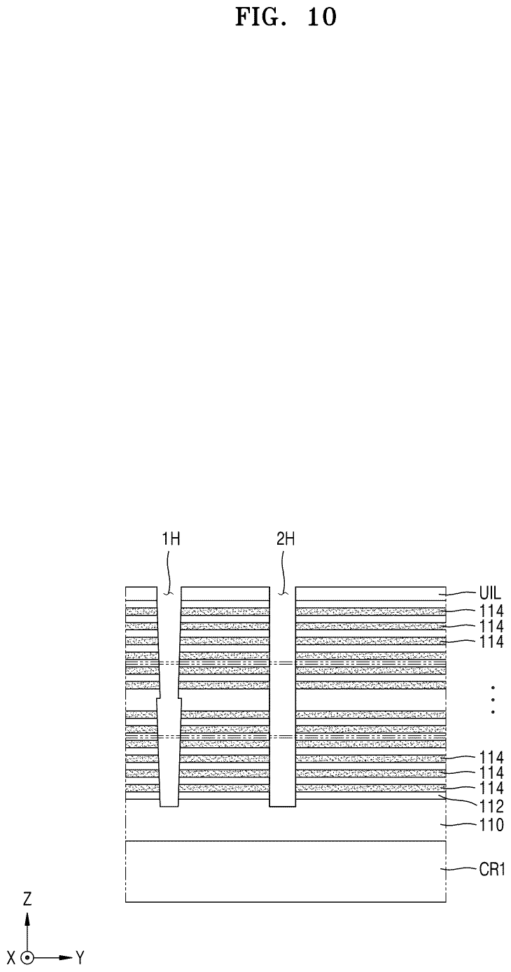

Referring to FIG. 10, a first hole 1H and a second hole 2H penetrating the upper insulating layer UIL and the stack structure of FIG. 9 may be formed. The first hole 1H may be configured to form the first word line cut structure (WLC1 of FIG. 6A), and the second hole 2H may be configured to form the first through via (THV1 of FIG. 6A). To form the first hole 1H and the second hole 2H, an etching process may be performed on portions of the upper insulating layer UIL and the stack structure, and the etching process may include a dry etching process, a wet etching process, or a combination thereof.

In some example embodiments, the second hole 2H may penetrate a portion of the first substrate 110, and the vertical level of the bottom of the second hole 2H may be between the vertical levels of the upper surface and the lower surface of the first substrate 110. In some example embodiments, the second hole 2H may entirely penetrate the first substrate 110, and the vertical level of the bottom of the second hole 2H may be identical to the vertical level of the lower surface of the first substrate 110.

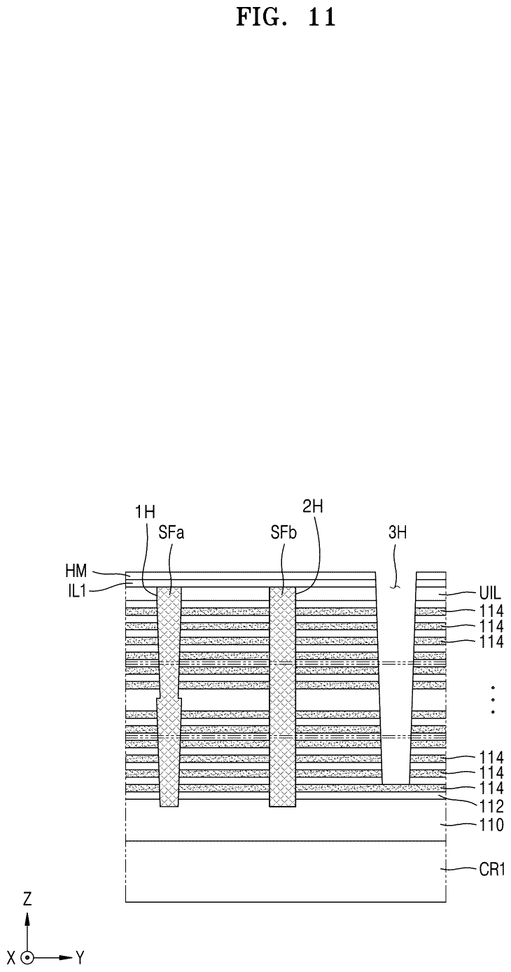

Referring to FIG. 11, a first sacrificial layer SFa filling the interior of the first hole 1H of FIG. 10 and a second sacrificial layer SFb filling the interior of the second hole 2H may be formed. The first sacrificial layer SFa and the second sacrificial layer SFb may each include a conductive material such as W, a silicon layer, a polycrystalline silicon layer, or a carbide layer, but are not limited thereto.

A first cover insulating layer IL1 may be formed on the result including the first sacrificial layer SFa and the second sacrificial layer SFb. The first cover insulating layer IL1 may be a silicon oxide layer, but one or more example embodiments are not limited thereto. Then, a hard mask HM including a plurality of holes corresponding to the gate line contacts (SFC of FIG. 6A) may be formed on the first cover insulating layer IL1, and a third hole 3H penetrating the first cover insulating layer IL1, the upper insulating layer UIL, and the stack structure through the holes may be formed.

The third hole 3H may be configured to form the gate line contact (SFC of FIG. 6A). To form the third hole 3H, an etching process may be performed on portions of the first cover insulating layer IL1, the upper insulating layer UIL, and the stack structure, and the etching process may include a dry etching process, a wet etching process, or a combination thereof.

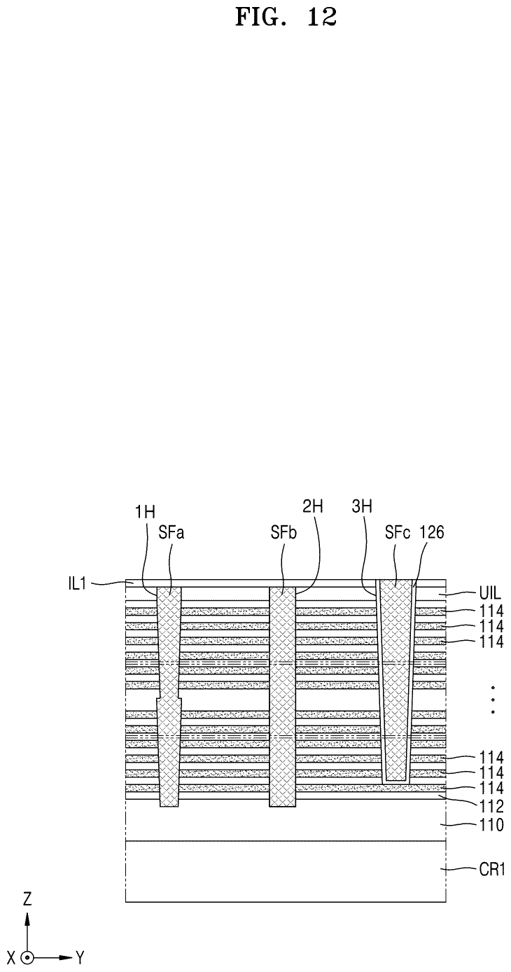

Referring to FIG. 12, the hard mask (HM of FIG. 11) may be removed from the result of FIG. 11, and a first gate insulating spacer 126 may be formed in the third hole 3H. The first gate insulating spacer 126 may be formed to conformally cover the inner wall and the bottom of the third hole 3H. A third sacrificial layer SFc may be formed in the third hole 3H where the first gate insulating spacer 126 is formed.

The third sacrificial layer SFc may fill the remaining space in the third hole 3H where the first gate insulating spacer 126 is formed. Similar to the first sacrificial layer SFa and the second sacrificial layer SFb, the third sacrificial layer SFC may include a conductive material such as W, a silicon layer, a polycrystalline silicon layer, or a carbide layer, but one or more example embodiments are not limited thereto.

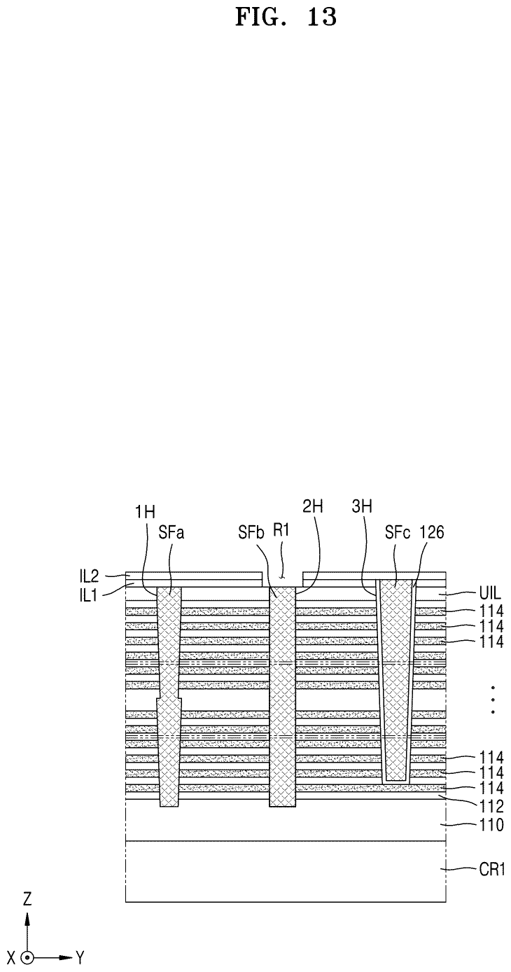

Referring to FIG. 13, a second cover insulating layer IL2 covering the result of FIG. 12 may be formed, and a first recess R1 penetrating the second cover insulating layer IL2 and the first cover insulating layer IL1 may be formed. The second sacrificial layer SFb in the second hole 2H may be exposed from the bottom of the first recess R1.

In this case, the upper surface of the first sacrificial layer SFa may be covered by the first cover insulating layer IL1 and the second cover insulating layer IL2 and thus may not be exposed, and the upper surface of the third sacrificial layer SFc may be covered by the second cover insulating layer IL2 and thus may not be exposed.

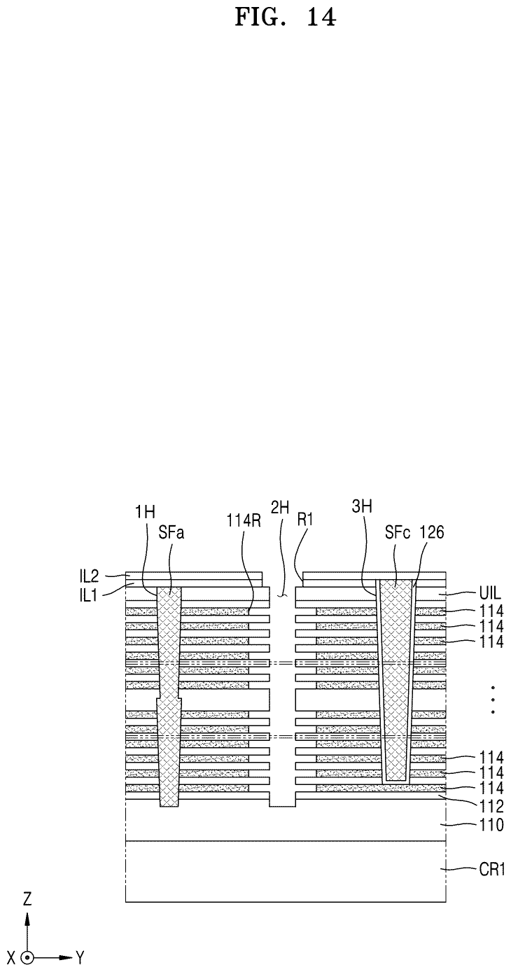

Referring to FIG. 14, the second sacrificial layer SFb in the second hole 2H may be removed through the first recess R1 of FIG. 13. Upon removal of the second sacrificial layer SFb, the sacrificial insulating layers 114 may be exposed through the sidewalls of the second hole 2H. Through the second hole 2H, portions of the sacrificial insulating layers 114 that are exposed through the sidewalls of the second hole 2H may be etched, thereby forming a sacrificial insulating layer recess 114R.

The above etching process may be a selective etching process using the difference in etch selectivity between the sacrificial insulating layers 114 and the first gate insulating layers 112. In addition, the above etching process may be a wet etching process. Through the etching process, the sidewalls of the second hole 2H that face the sacrificial insulating layers 114 may protrude to be farther from the central portion of the second hole 2H, compared to the sidewalls that face the first gate insulating layers 112.

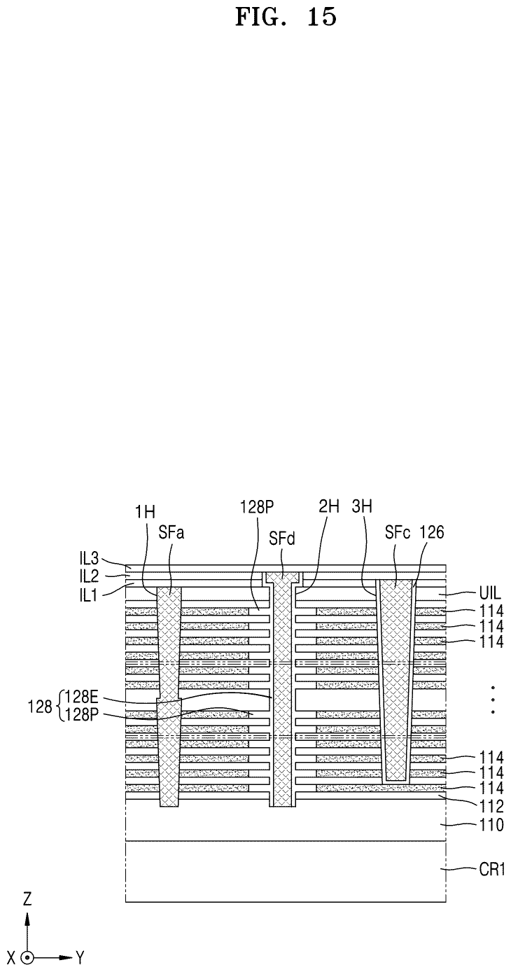

Referring to FIG. 15, in some example embodiments, the first insulating liner 128 may be formed on the result of FIG. 14, the first insulating liner 128 filling the sacrificial insulating layer recess 114R inside the second hole 2H and extending to the sidewalls (e.g., side boundaries) of the second hole 2H. In some example embodiments, the first insulating liner 128 filling the sacrificial insulating layer recess 114R inside the second hole 2H and extending to the sidewalls and the bottom of the second hole 2H may be formed.

In an example embodiment, to form the first insulating liner 128, an insulating layer that fills the sacrificial insulating layer recess 114R inside the second hole 2H and conformally covers the sidewalls and bottom (e.g., side and bottom boundaries) of the second hole 2H may be formed, and then a portion of the insulating layer that covers the bottom of the second hole 2H may be removed. In this case, the process of removing the portion of the insulating layer that covers the bottom of the second hole 2H may be omitted.

The first insulating liner 128 may include a first extension portion 128E conformally covering the sidewalls of the second hole 2H and a plurality of protrusions 128P protruding from the first extension portion 128E in the first horizontal direction (the X direction) and the second horizontal direction (the Y direction). The first protrusions 128P may be aligned along the sidewalls of the first extension portion 128E and spaced apart from each other in the vertical direction (the Z direction) with the first gate insulating layer 112 therebetween.

A fourth sacrificial layer SFd may be formed in the second hole 2H where the first insulating liner 128 is formed. The fourth sacrificial layer SFd may fill the remaining space of the second hole 2H where the first insulating liner 128 is formed. Similar to the first sacrificial layer SFa, the second sacrificial layer SFb, and the third sacrificial layer SFc, the fourth sacrificial layer SFd may include a conductive material such as W, a silicon layer, a polycrystalline silicon layer, or a carbide layer, but one or more example embodiments are not limited thereto.

On the result including the fourth sacrificial layer SFd, a third cover insulating layer IL3 covering the upper surfaces of the second cover insulating layer IL2, the first insulating liner 128, and the fourth sacrificial layer SFd may be formed. The third cover insulating layer IL3 may be a silicon oxide layer, but one or more example embodiments are not limited thereto.

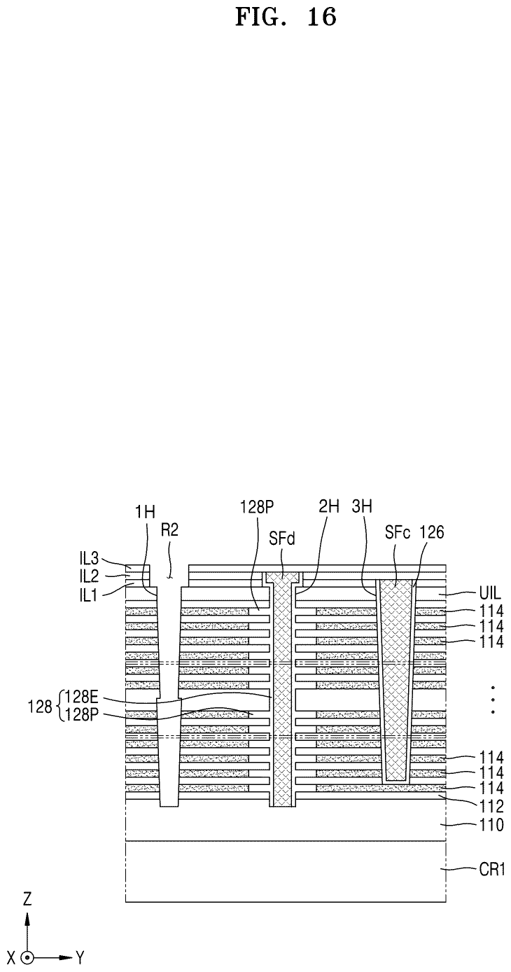

Referring to FIG. 16, a second recess R2 penetrating the third cover insulating layer IL3, the second cover insulating layer IL2, and the first cover insulating layer IL1 may be formed in the result of FIG. 15. The first sacrificial layer SFa in the first hole 1H may be exposed from the bottom of the second recess R2. In this case, the upper surface of the third sacrificial layer SFc may be covered by the second cover insulating layer IL2 and thus may not be exposed, and the upper surface of the fourth sacrificial layer SFd may be covered by the third cover insulating layer IL3 and thus may not be exposed.

Then, the first sacrificial layer SFa in the first hole 1H may be removed through the second recess R2. Upon removal of the first sacrificial layer SFa, the sacrificial insulating layers 114 may be exposed through the sidewalls (e.g., side boundaries) of the first hole 1H. Through the first hole 1H, the sacrificial insulating layers 114 exposed through the sidewalls of the first hole 1H may be etched and removed.

The above etching process may be a selective etching process using the difference in etch selectivity between the sacrificial insulating layers 114 and the first gate insulating layers 112.

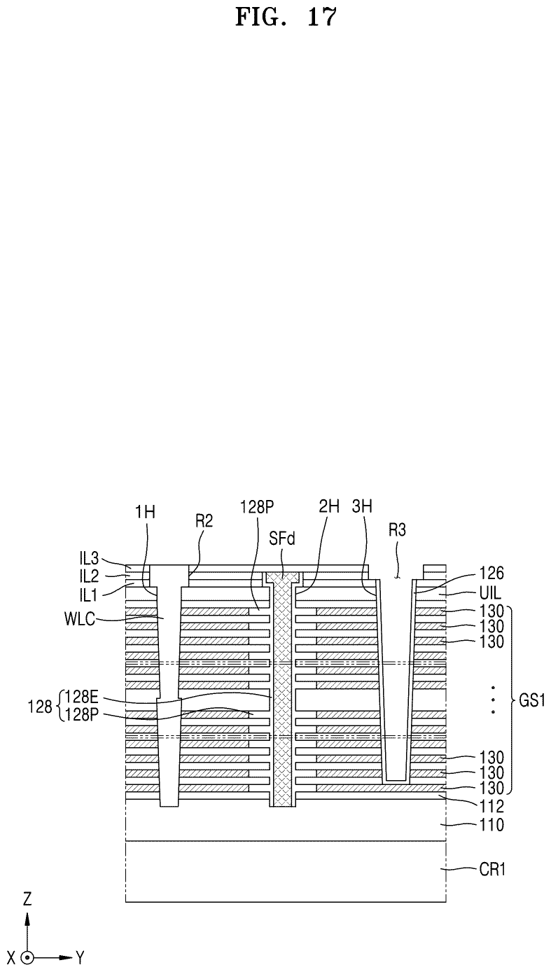

Referring to FIG. 17, on the result of FIG. 16, the first gate lines 130 may be formed in the space where the sacrificial insulating layers (114 of FIG. 16) are removed, and thus, the first gate stack GS1 may be formed.

Then, the word line cut structures WLC filling the interiors of the first hole 1H and the second recess R2 may be formed. Each word line cut structure WLC may include an insulating structure. In some example embodiments, the insulating structure may include silicon oxide, silicon nitride, silicon oxynitride, or a low-k dielectric material. For example, the insulating structure may include a silicon oxide layer, a silicon nitride layer, an SiON layer, an SiOCN layer, an SiCN layer, or a combination thereof. In some example embodiments, at least a portion of the insulating structure may include an air gap. The term “air” used in the present specification may refer to the atmosphere or other gases present during the manufacturing processes.

In addition, a third recess R3 penetrating the third cover insulating layer IL3 and the second cover insulating layer IL2 may be formed. The third sacrificial layer SFc in the third hole 3H may be exposed from the bottom of the third recess R3. In this case, the upper surface of the fourth sacrificial layer SFd may be covered by the third cover insulating layer lL3 and thus may not be exposed.

Then, the etching process of removing the third sacrificial layer SFc in the third hole 3H through the third recess R3 may be performed. Through the above etching process, the third sacrificial layer SFc may be removed, and thus, the first gate insulating spacer 126 covering the inner wall of the third hole 3H may be exposed. The etching process may be a selective etching process using the difference in etch selectivity between the third sacrificial layer SFc and the first gate insulating spacer 126, and after the etching process, the first gate insulating spacer 126 may remain in the third hole 3H.

After the sacrificial insulating layers 114 outside the first gate insulating spacer 126 are selectively etched and removed, the first gate lines 130 may be formed in the space where the sacrificial insulating layers (114 of FIG. 16) are removed, and thus, the first gate stack GS1 may be formed.

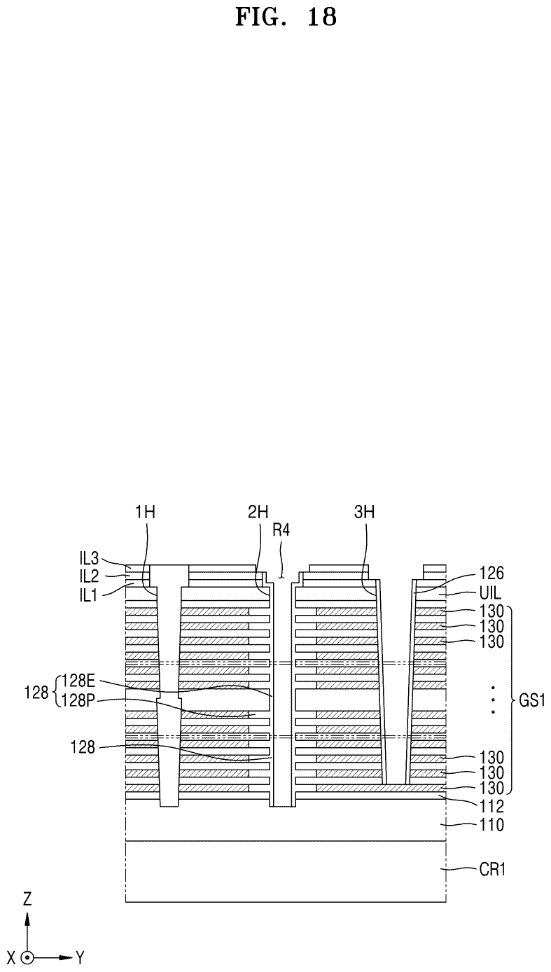

Referring to FIG. 18, the etching process may be performed to remove a portion of the first gate insulating spacer 126 of FIG. 17 that covers the first gate line 130. The etching process may be performed as an anisotropic etching process, and for example, Reactive Ion Etching (RIE) or plasma etching may be used as a dry etching process. Through the above etching process, the first gate line 130 may be exposed through the bottom of the third hole 3H. However, even after the etching process, the first gate insulating spacer 126 covering the sidewalls of the third hole 3H may remain.

Subsequently, a fourth recess R4 penetrating the third cover insulating layer IL3 may be formed. The fourth sacrificial layer SFd in the second hole 2H may be exposed from the bottom of the fourth recess R4. Then, an etching process of removing the fourth sacrificial layer SFd in the second hole 2H through the fourth recess R4 may be performed. Through the above etching process, the fourth sacrificial layer SFd may be removed, and thus, the first insulating liner 128 covering the inner wall of the second hole 2H may be exposed. The etching process may be a selective etching process using the difference in etch selectivity between the fourth sacrificial layer SFd and the first insulating liner 128, and after the etching process, the first insulating liner 128 may remain in the second hole 2H.

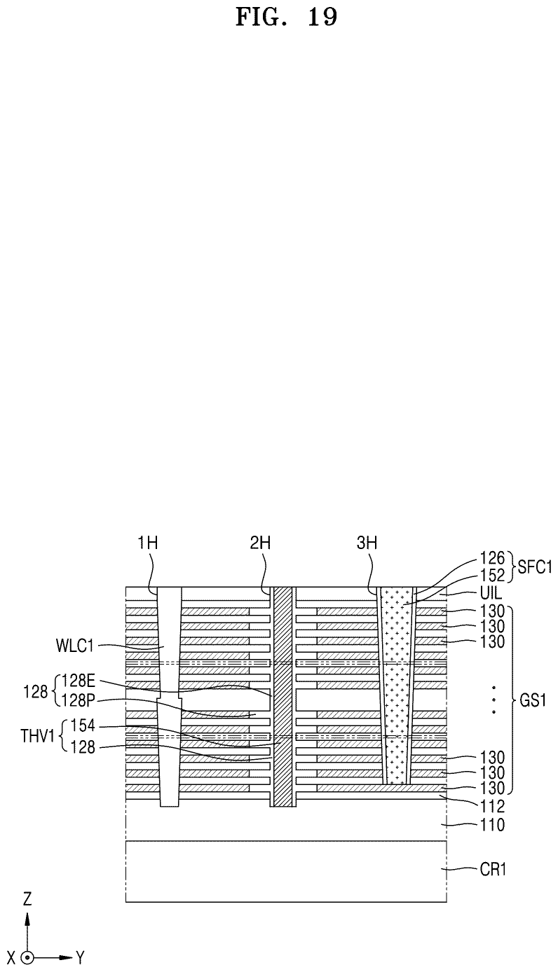

Referring to FIG. 19, the first gate contact plug 152 may be formed by depositing a conductive material inside the third hole 3H. In addition, the first conductive plug 154 may be formed by depositing a conductive material inside the second hole 2H. For example, the conductive material may be deposited using Chemical Vapor Deposition (CVD), Physical Vapor Deposition (PVD), or Atomic Layer Deposition (ALD). The conductive material may include W, Ti, Ta, Cu, Al, TiN, TaN, WN, or a combination thereof, but one or more example embodiments are not limited thereto.

Then, a Chemical Mechanical Polishing (CMP) process may be performed to flatten the upper surface of the result on which the first gate contact plug 152 and the first conductive plug 154 are formed. Through the CMP process, the first cover insulating layer IL1, the second cover insulating layer IL2, and the third cover insulating layer IL3 on the upper portion of the upper insulating layer UIL may be removed. Simultaneously with the removal of the first cover insulating layer IL1, the second cover insulating layer IL2, and the third cover insulating layer IL3, portions of the first gate contact plug 152 and the first conductive plug 154 that overlap the first cover insulating layer IL1, the second cover insulating layer IL2, and the third cover insulating layer IL3 in the first horizontal direction (the X direction) and the second horizontal direction (the Y direction) may be removed together. Thus, the first through via THV1 and the first gate line contact SFC1 may be formed.

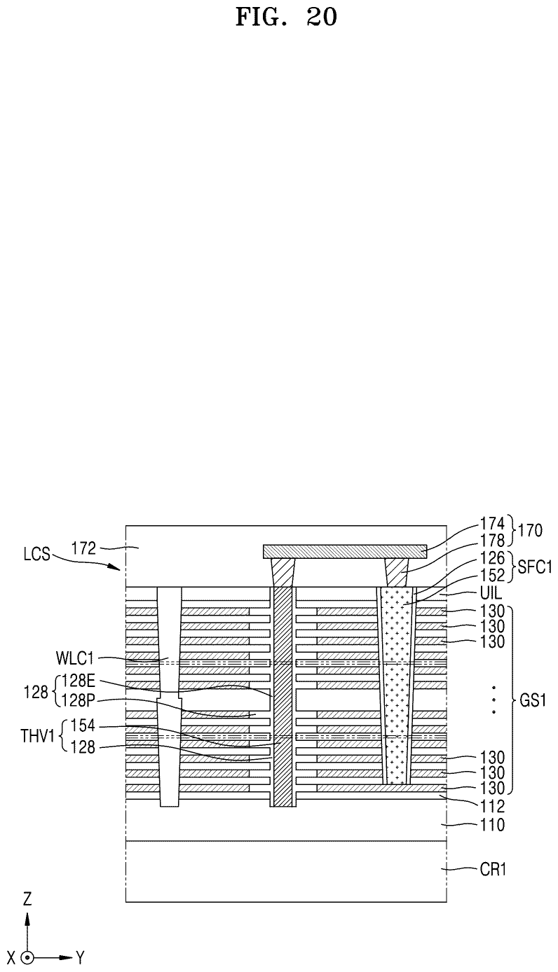

Referring to FIG. 20, the first upper insulating layer 172 may be formed on the upper surface of the result of FIG. 19, and the first conductive studs 178 and the first upper wiring layer 174 contacting at least two of the first conductive studs 178 may be formed. The first conductive studs 178 may each be formed on the upper surface of the first through via THV1 or the upper surface of the first gate line contact SFC1. The first upper wiring layer 174 may be formed on the upper surfaces of the first conductive studs 178. The first upper insulating layer 172 may be formed to cover the surface of each of the first conductive studs 178 and the first upper wiring layer 174.

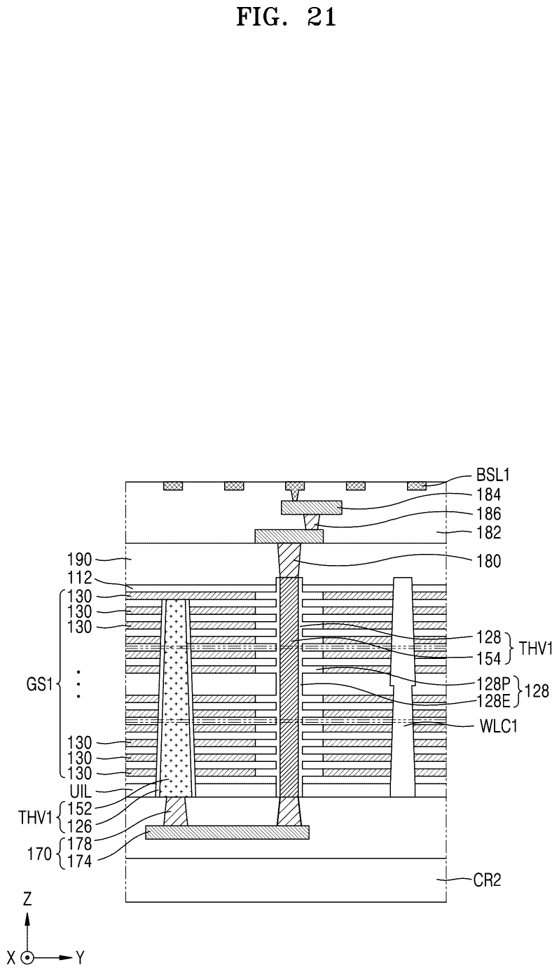

Referring to FIG. 21, after removing the first carrier substrate (CR1 of FIG. 20), the result of FIG. 20 may be arranged on a second carrier substrate CR2 such that the first conductive studs 178 and the first upper wiring layer 174 face the upper surface of the second carrier substrate CR2.

Then, the first substrate (110 of FIG. 20) may be removed, and the first insulating layer 190 may be formed in the region where the first substrate is removed. Sequentially, the first through contact 180 connected to the first through via THV1 by penetrating the first insulating layer 190 may be formed, and the first lower insulating layer 182, the first lower wiring layer 184, and the first lower contact plug 186 may be formed on the first insulating layer 190. The first lower insulating layer 182 may be formed to cover the surfaces of the first lower wiring layer 184 and the first lower contact plug 186. Then, a plurality of local regions may be removed from the upper surface of the first lower insulating layer 182, and a plurality of first bonding metal pads BSL1 may be formed in the local regions.

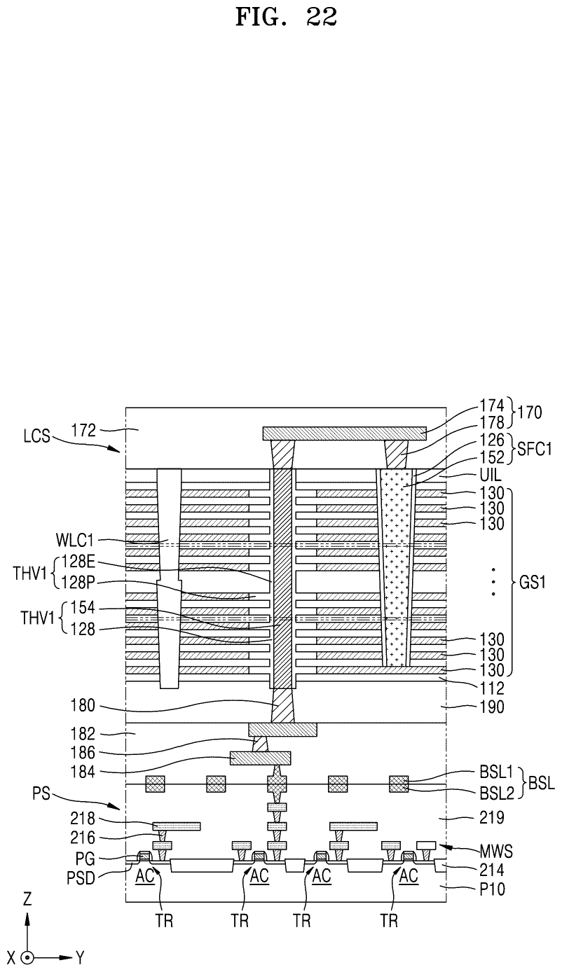

Referring to FIG. 22, the second carrier substrate (CR2 of FIG. 21) is removed. The result of FIG. 21, that is, the lower cell array stack LCS, may be aligned on the peripheral circuit stack PS such that the first bonding metal pads BSL1 face the second bonding metal pads BSL2 of the peripheral circuit stack PS, and the first bonding metal pads BSL1 may be bonded to the second bonding metal pads BSL2.

In some example embodiments, the first bonding metal pads BSL1 may be directly bonded to the second bonding metal pads BSL2 without a separate adhesive layer by pressing the lower cell array stack LCS towards the peripheral circuit stack PS. In some example embodiments, before the first bonding metal pads BSL1 and the second bonding metal pads BSL2 are bonded, a surface treatment process using hydrogen plasma may be further performed on the exposed surfaces of the first bonding metal pads BSL1 and the second bonding metal pads BSL2 to increase adhesion therebetween. The first bonding metal pads BSL1 and the second bonding metal pads BSL2 may each include Cu, Al, or W, but one or more example embodiments are not limited thereto.

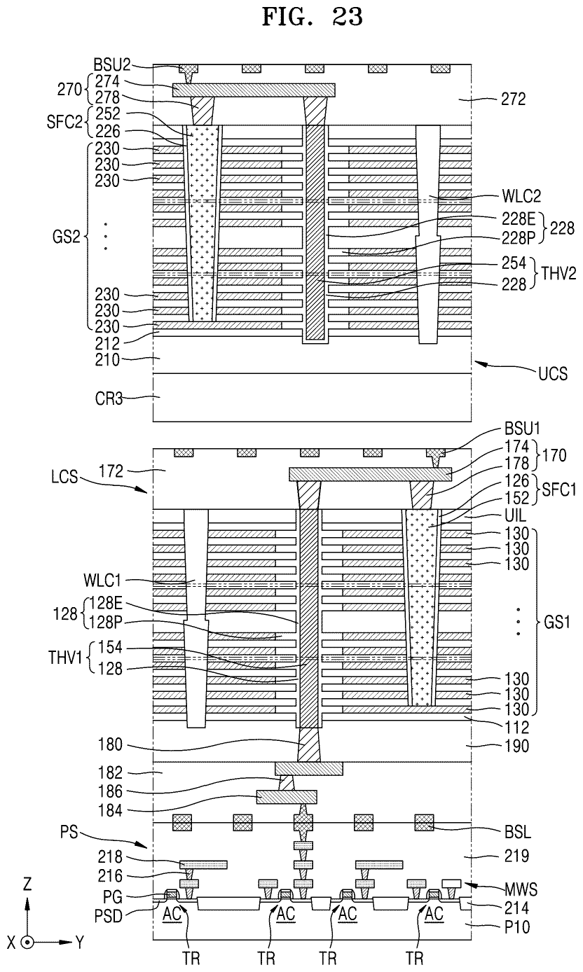

Referring to FIG. 23, a plurality of local regions may be removed from the upper surface of the first upper insulating layer 172 on the lower cell array stack LCS, and the first bonding metal pads BSU1 may be formed in the local regions.

Independently from the manufacturing process of the lower cell array stack LCS, the upper cell array stack UCS may be formed on a third carrier substrate CR3, similar to the formation of the lower cell array stack LCS. Then, a plurality of local regions may be removed from the upper surface of the second lower insulating layer 272 of the upper cell array stack UCS, and the second bonding metal pads BSU2 may be formed in the local regions.

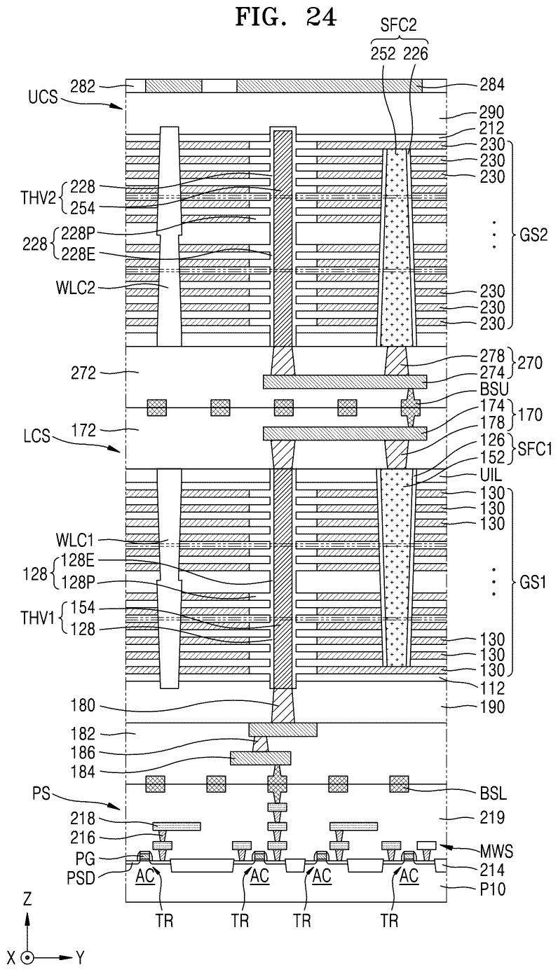

Referring to FIG. 24, after the removal of the third carrier substrate (CR3 of FIG. 23), the lower cell array stack LCS of FIG. 23 may be aligned on the lower cell array stack LCS such that the first bonding metal pads BSU1 face the second bonding metal pads BSU2 of the upper cell array stack UCS, and the first bonding metal pads BSU1 may be bonded to the second bonding metal pads BSU2.

In some example embodiments, the first bonding metal pads BSU1 may be directly bonded to the second bonding metal pads BSU2 without a separate adhesive layer by pressing the upper cell array stack UCS towards the lower cell array stack LCS. In some example embodiments, before the first bonding metal pads BSU1 and the second bonding metal pads BSU2 are bonded, a surface treatment process using hydrogen plasma may be further performed on the exposed surfaces of the first bonding metal pads BSL1 and the second bonding metal pads BSL2 to increase adhesion therebetween. The first bonding metal pads BSU1 and the second bonding metal pads BSU2 may each include Cu, Al, or W, but one or more example embodiments are not limited thereto.

Then, the second substrate (210 of FIG. 23) may be removed, and the second insulating layer 290 may be formed in the region where the second substrate (210 of FIG. 23) is removed. The second upper wiring layer 284 may be formed on the second insulating layer 290, and the second upper insulating layer 282 covering the surface of the second upper wiring layer 284 may be formed.

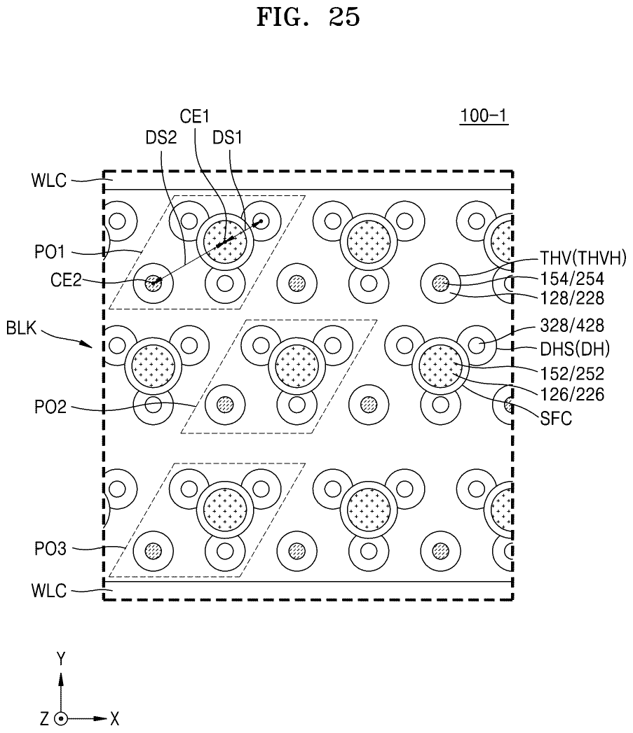

FIG. 25 is a planar layout of a memory device according to an example embodiment.

For example, compared to the planar layout illustrating the extension region EXT of FIG. 4A, a memory device 100-1 may be the same as the memory device 100 of FIG. 4A except for the arrangement of the gate line contacts SFC. Compared to the planar layout illustrating the extension region EXT of FIG. 4A, the memory device 100-1 may be the same as the memory device 100 except that a greater number of gate line contacts SFC are arranged in the second horizontal direction (the Y direction).

In FIG. 25, the same reference symbols as in FIGS. 4A to 8 denote the same components, and detailed descriptions thereof are omitted. The memory cell block BLK may include word line cut structures WLC extending in the first horizontal direction (the X direction) and spaced apart in the second horizontal direction (the Y direction). The memory cell block BLK may include gate line contacts SFC, dummy structures DHS, and through vias THV inwards from the word line cut structure WLC.

The memory cell block BLK may include a plurality of unit portions PO1 to PO3 each including the gate line contact SFC, the dummy structure DHS, and the through via THV. The unit portions PO1 to PO3 may be arranged in a zigzag form in the second horizontal direction (the Y direction).

The gate line contacts SFC may be spaced apart from each other in the second horizontal direction (the Y direction) in a zigzag form and aligned apart from each other in the first horizontal direction (the X direction). The gate line contact SFC may include a gate contact plug 152/252 and a gate insulating spacer 126/226 that surrounds the sidewalls of the gate contact plugs 152/252.

The dummy structure DHS may be arranged adjacent to the gate line contact SFC. Three dummy structures DHS may be arranged around each gate line contact SFC to surround the same. The dummy structure DHS may include a dummy insulating layer 328/428 arranged in a dummy hole DH.

The through via THV may be arranged apart from the gate line contact SFC in the horizontal direction. The through via THV may be arranged in a through hole THVH. The through via THV may include a conductive plug 154/254 and an insulating liner 128/228 that surrounds the conductive plug 154/254. In a limited sense, the through via THV may only refer to the conductive plug 154/254.

As shown in FIG. 25, a second distance DS2 between the gate line contact SFC and the through via THV in the horizontal direction may be greater than a first distance DS1 between the gate line contact SFC and the dummy structure DHS in the horizontal direction. The second distance DS2 between the central point CE1 of the gate line contact SFC and the central point CE3 of the through via THV in the horizontal direction may be greater than the first distance DS1 between the central point CE1 of the gate line contact SFC and the central point CE2 of the dummy structure DHS in the horizontal direction.

In some example embodiments, the second distance DS2 may be twice the first distance DS1. In some example embodiments, the second distance DS2 may be in a range from about 600 nm to about 800 nm, and the first distance DS1 may be in a range from about 200 nm to about 400 nm.

As described, in the memory device 100-1, the through vias THV may be arranged apart from the gate line contacts SFC in the horizontal direction such that the formation of cracks between the gate line contacts SFC and the through vias THV may be restricted. Accordingly, in the memory device 100-1, three-dimensionally arranged memory cells are included to improve the integration, and crack formation is reduced or prevented to enhance reliability of the memory device 100-1.

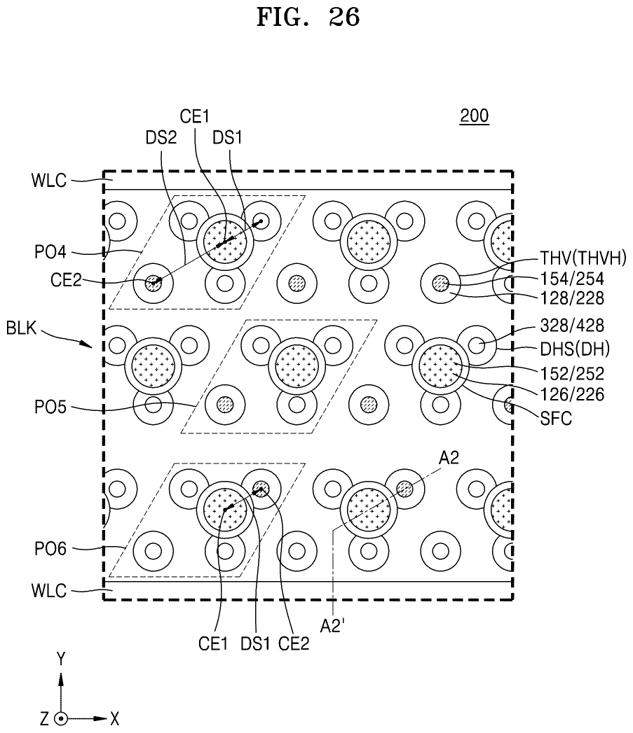

FIG. 26 is a planar layout of a memory device according to an example embodiment.

For example, compared to the planar layout illustrating the extension region EXT of FIG. 4A, a memory device 200 may be the same as the memory device 100 of FIG. 4A except for the arrangement of gate line contacts SFC and through vias THV. Compared to the planar layout illustrating the extension region EXT of FIG. 4A, the memory device 200 may be the same as the memory device 100 except that a greater number of gate line contacts SFC are arranged in the second horizontal direction (the Y direction) and the arrangement of the through vias THV differ accordingly.

In FIG. 26, the same reference symbols as in FIGS. 4A to 8 denote the same components, and detailed descriptions thereof are omitted. The memory cell block BLK may include word line cut structures WLC extending in the first horizontal direction (the X direction) and spaced apart in the second horizontal direction (the Y direction). The memory cell block BLK may include gate line contacts SFC, dummy structures DHS, and through vias THV inwards from the word line cut structure WLC.

The memory cell block BLK may include a plurality of unit portions PO4 to PO6 each including the gate line contact SFC, the dummy structure DHS, and the through via THV. The unit portions PO4 to PO6 may be arranged in a zigzag form in the second horizontal direction (the Y direction).

The gate line contacts SFC may be spaced apart from each other in the second horizontal direction (the Y direction) in a zigzag form and aligned apart from each other in the first horizontal direction (the X direction). The gate line contact SFC may include the gate contact plug 152/252 and the gate insulating spacer 126/226 that surrounds the sidewalls of the gate contact plugs 152/252.

The dummy structure DHS may be arranged adjacent to the gate line contact SFC. Three dummy structures DHS may be arranged around each gate line contact SFC to surround the same. The dummy structure DHS may include a dummy insulating layer 328/428 arranged in a dummy hole DH.

In the unit portions PO4 and PO5, the through vias THV may be spaced apart from the gate line contacts SFC in the horizontal direction. In the unit portion PO6, the through via THV may be arranged adjacent to the gate line contact SFC. The through via THV may be arranged in a through hole THVH. The through via THV may include the conductive plug 154/254 and the insulating liner 128/228 that surrounds the conductive plug 154/254. In a limited sense, the through via THV may only refer to the conductive plugs 154/254.

As shown in FIG. 26, in the unit portions PO4 and PO5, the second distance DS2 between the gate line contact SFC and the through via THV in the horizontal direction may be greater than the first distance DS1 between the gate line contact SFC and the dummy structure DHS in the horizontal direction.

In the unit portions PO4 and PO5, the second distance DS2 between the central point CE1 of the gate line contact SFC and the central point CE3 of the through via THV in the horizontal direction may be greater than the first distance DS1 between the central point CE1 of the gate line contact SFC and the central point CE2 of the dummy structure DHS in the horizontal direction. In the unit portion PO6, the distance between the gate line contact SFC and the through via THV in the horizontal direction may be the first distance DS1.

In some example embodiments, the second distance DS2 may be twice the first distance DS1. In some example embodiments, the second distance DS2 may be in a range from about 600 nm to about 800 nm, and the first distance DS1 may be in a range from about 200 nm to about 400 nm.

As described, in the memory device 200, the through vias THV may be arranged spart from the gate line contacts SFC in the horizontal direction such that the generation of cracks between the gate line contacts SFC and the through vias THV may be restricted. In addition, in the memory device 200, the through vias THV are arranged adjacent to the gate line contacts SFC in the horizontal direction such that the design freedom in the arrangement of the gate line contacts SFC and the through vias THV may increase.

Accordingly, in the memory device 200, three-dimensionally arranged memory cells are included to improve the integration, and crack formation is reduced or prevented to enhance reliability of the memory device 200. Moreover, the through vias THV are arranged adjacent to the gate line contacts SFC in the memory device 200 such that the design freedom may increase.

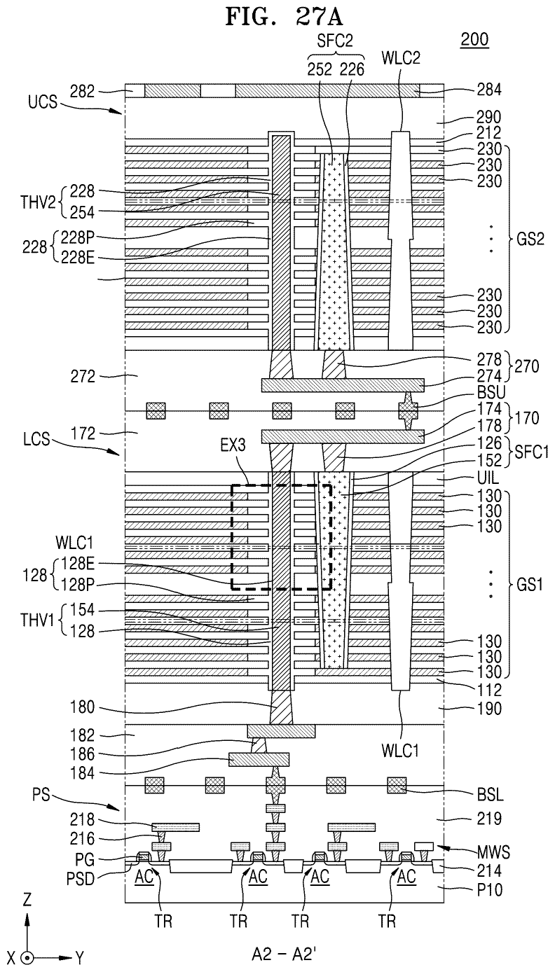

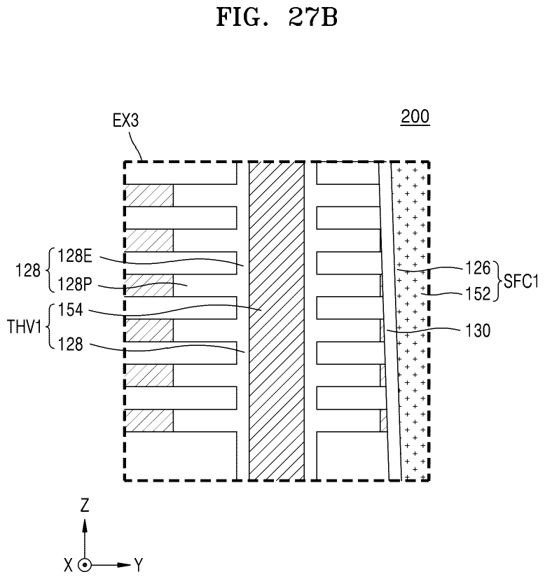

FIG. 27A is a cross-sectional view of the memory device 200, taken along a line A2-A2′ of FIG. 26, and FIG. 27B illustrates a region corresponding to region “EX3” of FIG. 27A.

For example, because the memory device 200 is substantially similar to the memory device 100 described above, the differences therebetween are mainly described below. The same reference symbols as those for the memory device 100 denote the same components, and repeated descriptions thereof are omitted.

The memory device 200 may include a peripheral circuit stack PS and a plurality of cell array stacks CS, for example, a lower cell array stack LCS and an upper cell array stack UCS, which are arranged on the peripheral circuit stack PS to overlap the same in the vertical direction (the Z direction).

As shown in FIG. 26, in the extension region EXT of the cell array stack CS described above with reference to FIG. 4A, the gate line contacts SFC and the through vias THV adjacent to the gate line contacts SFC may be arranged. The gate line contacts SFC may be arranged apart from each other in the first horizontal direction (the X direction), and three through vias THV may be arranged to surround each gate line contact SFC.

The through via THV may include the conductive plug 154/254 and the insulating liner 128/228 that surrounds the conductive plug 154/254. The insulating liner 128/228 may include an extension portion 128E/228E surrounding the sidewalls of the conductive plug 154/254 and a plurality of protrusions 128P/228P protruding from the extension portion 128E/228E in the first horizontal direction (the X direction) and the second horizontal direction (the Y direction).

As shown in FIGS. 27A and 27B, the first protrusions 128P may be in contact with the first gate line contact SFC1 in the horizontal direction (the X direction and the Y direction), and the second protrusions 228P may be in contact with the second gate line contact SFC2 in horizontal direction (the X direction and the Y direction).

Some of the first protrusions 128P may contact the first gate insulating spacer 126 of the first gate line contact SFC1 in the horizontal direction (the X direction and the Y direction). Some of the second protrusions 228P may contact the second gate insulating spacer 226 of the second gate line contact SFC2 in the horizontal direction (the X direction and the Y direction).

The others of the first protrusions 128P may be spaced apart from each other in the horizontal direction (the X direction and the Y direction) with the first gate line contact SFC1 and some of the first gate lines 130 therebetween. The others of the second protrusions 228P may be spaced apart from each other in the horizontal direction (the X direction and the Y direction) with the second gate line contact SFC2 and some of the second gate lines 230 therebetween.

Some of the first protrusions 128P contacting the first gate insulating spacer 126 in the horizontal direction (the X direction and the Y direction) may be at a higher vertical level than others of the first protrusions 128P that are spaced apart in the horizontal direction (the X direction and the Y direction) with the first gate line contact SFC1 and some of the first gate lines 130 therebetween.

Some of the second protrusions 228P contacting the second gate insulating spacer 226 in the horizontal direction (the X direction and the Y direction) may be at a lower vertical level than others of the second protrusions 228P that are spaced apart in the horizontal direction (the X direction and the Y direction) with the second gate line contact SFC2 and some of the second gate lines 230 therebetween.

At least one of the first through vias THV1 and at least one of the second through vias THV2 may be electrically connected to the first gate line contact SFC1 and the second gate line contact SFC2, respectively.

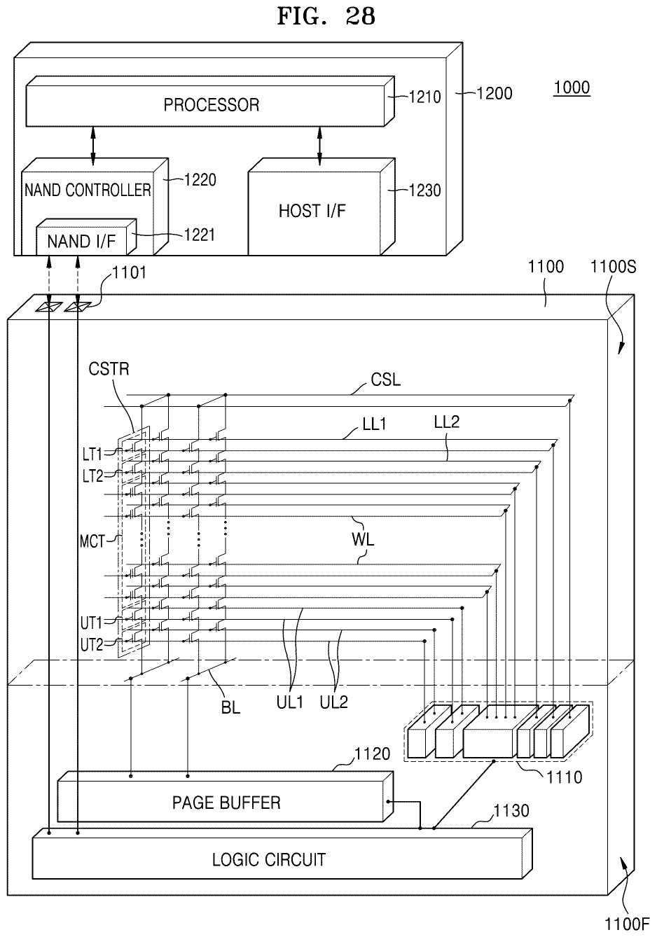

FIG. 28 schematically illustrates a data storage system 1000 including a memory device, according to an example embodiment.

For example, the data storage system 1000 may include one or more memory devices 1100 and a memory controller 1200 electrically connected to the memory devices 1100. The data storage system 1000 may be, for example, a solid-state drive (SSD) device, a Universal Serial Bus (USB), a computing system, a medical device, or a communication device, all of which include at least one memory device 1100.

The memory device 1100 may be a non-volatile semiconductor device, and for example, the memory device 1100 may be a NAND flash semiconductor device including one of the memory devices 10, 100, 100-1, and 200 described above. The memory device 1100 may include a first structure 1100F and a second structure 1100S on the first structure 1100F. The first structure 1100F may be a peripheral circuit structure including a row decoder 1110, a page buffer 1120, and a logic circuit 1130.

The second structure 1100S may be a memory cell structure that includes a bit line BL, a common source line CSL, a plurality of word lines WL, a first string selection line UL1, a second string selection line UL2, a first ground selection line LL1, a second ground selection line LL2, and a plurality of memory cell strings CSTR located between the bit line BL and the common source line CSL.

In the second structure 1100S, each memory cell string CSTR may include ground selection transistors LT1 and LT2 that are adjacent to the common source line CSL, string selection transistors UT1 and UT2 that are adjacent to the bit line BL, and memory cell transistors MCT that are arranged between the ground selection transistors LT1 and LT2 and the string selection transistors UT1 and UT2. The number of ground selection transistors LT1 and LT2 and the number of string selection transistors UT1 and UT2 may vary according to example embodiments.

In some example embodiments, the ground selection lines LL1 and LL2 may be connected to gate electrodes of the ground selection transistors LT1 and LT2, respectively. The word line WL may be connected to a gate electrode of the memory cell transistor MCT. The first string selection line UL1 and the second string selection line UL2 may be connected to gate electrodes of the string selection transistors UT1 and UT2, respectively.

The common source line CSL, the first ground selection line LL1, the second ground selection line LL2, the word lines WL, the first string selection line UL1, and the second string selection line UL2 may be connected to the row decoder 1110. The bit lines BL may be electrically connected to the page buffer 1120.

The memory device 1100 may communicate with the memory controller 1200 through an input/output pad 1101 that is electrically connected to the logic circuit 1130.

The memory controller 1200 may include a processor 1210, a NAND controller 1220, and a host interface 1230. In some example embodiments, the data storage system 1000 may include a plurality of memory devices 1100, and in this case, the memory controller 1200 may control the memory devices 1100.

The processor 1210 may control overall operations of the data storage system 1000 including the memory controller 1200. The processor 1210 may operate according to specific firmware and control the NAND controller 1220 to access the memory device 1100. The NAND controller 1220 may include a NAND interface 1221 processing communication with the memory device 1100.

Through the NAND interface 1221, a control command for controlling the memory device 1100, data to be written on the memory cell transistors MCT of the memory device 1100, data to be read from the memory cell transistors MCT of the memory device 1100, and the like may be transmitted. The host interface 1230 may provide a communication function between the data storage system 1000 and an external host. When receiving a control command from an external host through the host interface 1230, the processor 1210 may control the memory device 1100 in response to the control command.

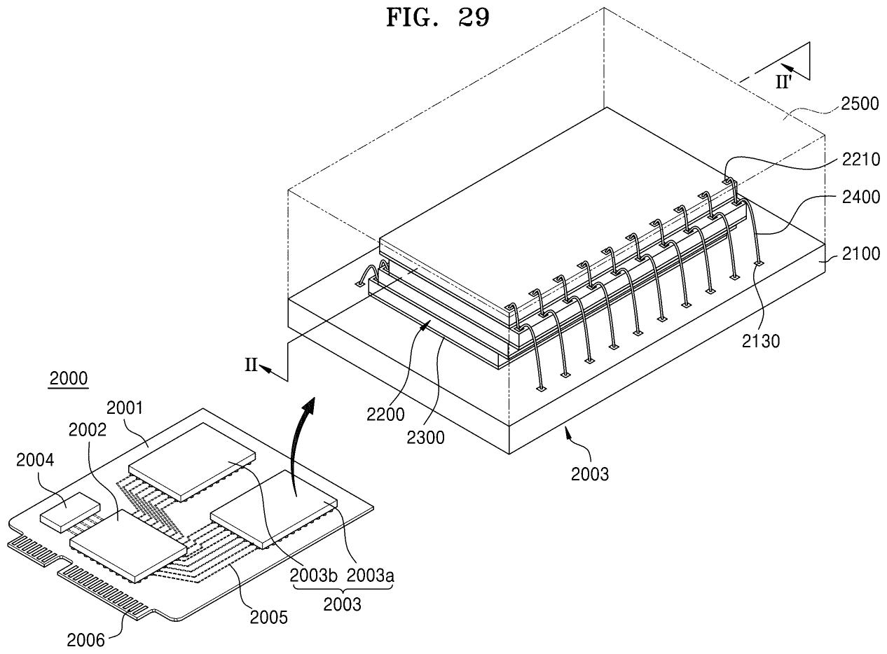

FIG. 29 schematically illustrates a data storage system 2000 including a memory device, according to an example embodiment.

For example, the data storage system 200 may include a main substrate 2001, a memory controller 2002 mounted on the main substrate 2001, one or more semiconductor packages 2003, and Dynamic Random Access Memory (DRAM) 2004. The semiconductor package 2003 and the DRAM 2004 may be connected to the memory controller 2002 via a plurality of wiring patterns 2005 formed on the main substrate 2001.

The main substrate 2001 may include a connector 2006 including a plurality of pins coupled to the external host. The number and arrangement of pins in the connector 2006 may vary depending on the communication interface between the data storage system 2000 and the external host. In some example embodiments, the data storage system 2000 may communicate with the external host according to any one of interfaces, for example, USB, Peripheral Component Interconnect Express (PCI-Express), Serial Advanced Technology Attachment (SATA), and M-Phy for Universal Flash Storage (UFS).

In some example embodiments, the data storage system 2000 may operate using the power supplied by the external host through the connector 2006. The data storage system 2000 may further include a Power Management Integrated Circuit (PMIC) configured to distribute the power from the external host to the memory controller 2002 and the semiconductor package 2003.

The memory controller 2002 may write data on the semiconductor package 2003 or read data therefrom and may improve the operation speed of the data storage system 2000.

The DRAM 2004 may be buffer memory for reducing a speed gap between the external host and the semiconductor package 2003 that is data storage space. The DRAM 2004 included in the data storage system 2000 may also function as cache memory and provide space for temporarily storing data during control operations performed on the semiconductor package 2003. When the data storage system 2000 includes the DRAM 2004, the memory controller 2002 may further include a DRAM controller to control the DRAM 2004, in addition to a NAND controller for controlling the semiconductor package 2003.

The semiconductor package 2003 may include a first semiconductor package 2003a and a second semiconductor package 2003b that are spaced apart from each other. Each of the first semiconductor package 2003a and the second semiconductor package 2003b may be a semiconductor package including a plurality of semiconductor chips 2200. Each of the first semiconductor package 2003a and the second semiconductor package 2003b may include a package substrate 2100, a plurality of semiconductor chips 2200 on the package substrate 2100, an adhesive layer 2300 arranged on a lower surface of each semiconductor chip 2200, a connection structure 2400 electrically connecting the semiconductor chips 2200 to the package substrate 2100, and a molding layer 2500 covering, on the package substrate 2100, the semiconductor chips 2200 and the connection structure 2400.

The package substrate 2100 may be a printed circuit board including a plurality of package upper pads 2130. Each semiconductor chip 2200 may include an input/output pad 2210. The input/output pad 2210 may correspond to the input/output pad 1101 of FIG. 28. Each semiconductor chip 2200 may include at least one of the memory devices 10, 100, 100-1, and 200 described above.

In some example embodiments, the connection structure 2400 may be bonding wire electrically connecting the input/output pad 2210 to the package upper pad 2130. Therefore, in the first semiconductor package 2003a and the second semiconductor package 2003b, the semiconductor chips 2200 may be electrically connected to each other in a bonding wire manner and electrically connected to the package upper pads 2130 of the package substrate 2100. In some example embodiments, in the first semiconductor package 2003a and the second semiconductor package 2003b, the semiconductor chips 2200 may be electrically connected to each other through a connection structure including a through silicon via (TSV), instead of the connection structure 2400 that is the bonding wire.

In some example embodiments, the memory controller 2002 and the semiconductor chips 2200 may be included in one package. In an example embodiment, the memory controller 2002 and the semiconductor chips 2200 may be mounted on an interposer substrate that is separate from the main substrate 2001 and may be connected to each other via wiring formed on the interposer substrate.

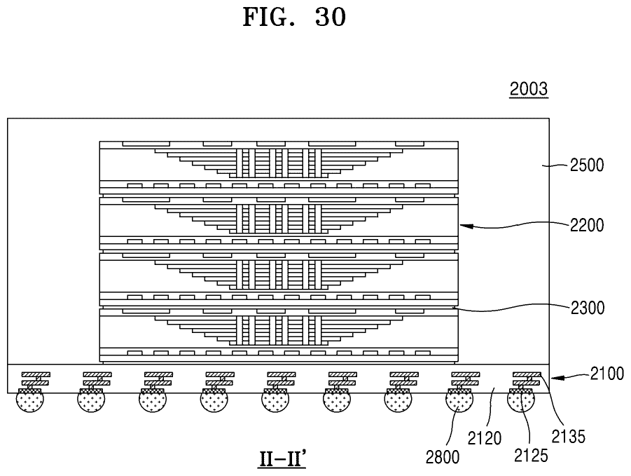

FIG. 30 is a schematic cross-sectional view of the semiconductor package 2003 including a memory device, according to an example embodiment.

For example, FIG. 30 is a cross-sectional view of the semiconductor package 2003, taken along a line II-II′ of FIG. 29. In the semiconductor package 2003, the package substrate 2100 may be a printed circuit board. The package substrate 2100 may include a package substrate body portion 2120, the package upper pads (2130, see FIG. 29) on the upper surface of the package substrate body portion 2120, a plurality of lower pads 2125 arranged on or exposed through the lower surface of the package substrate body portion 2120, and a plurality of internal wires 2135 electrically connecting the package upper pads (2130, see FIG. 29) to the lower pads 2125 within the package substrate body portion 2120.

As shown in FIG. 30, the package upper pads 2130 may be electrically connected to the connection structures 2400. As shown in FIG. 30, the lower pads 2125 may be connected to the wiring patterns 2005 on the main substrate 2001 of the data storage system 2000 of FIG. 29 via a plurality of conductive bumps 2800. Each semiconductor chip 2200 may include at least one of the memory devices 10, 100, 100-1, and 200 described above.

Any functional blocks shown in the figures and described above may be implemented in processing circuitry such as hardware including logic circuits, a hardware/software combination such as a processor executing software, or a combination thereof. For example, the processing circuitry more for example may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. A memory device comprising:
a peripheral circuit stack comprising a circuit substrate and a plurality of circuits thereon;
a first gate stack on the peripheral circuit stack, the first gate stack comprising a plurality of first gate lines stacked in a vertical direction;
a first vertical channel structure penetrating the first gate stack;
a plurality of first gate line contacts penetrating at least a portion of the first gate stack, each of the plurality of first gate line contacts electrically connected to any one first gate line selected from among the plurality of first gate lines;
a plurality of first dummy structures being adjacent to the plurality of first gate line contacts in a horizontal direction, the plurality of first dummy structures penetrating the first gate stack;
a plurality of first through vias each being apart from a corresponding one of the plurality of first gate line contacts in the horizontal direction, the plurality of first through vias penetrating the first gate stack, each of the plurality of first through vias connected to any one of the plurality of circuits of the peripheral circuit stack; and
a lower cell array stack comprising a first wiring structure that electrically connects at least any one of the plurality of first through vias to a corresponding one of the plurality of first gate line contacts,
wherein a distance between a select one of the plurality of first gate line contacts and a corresponding one of the plurality of first through vias adjacent thereto in the horizontal direction is greater than a distance between the select one of the plurality of first gate line contacts and a corresponding one of the plurality of first dummy structures adjacent thereto in the horizontal direction.

2. The memory device of claim 1, wherein a distance between a central point of the select one of the plurality of first gate line contacts and a central point of one of the plurality of first through vias adjacent to thereto in the horizontal direction is greater than a distance of the central point of the select one of the plurality of first gate line contacts and a central point of one of the plurality of first dummy structures adjacent thereto in the horizontal direction.

3. The memory device of claim 1, wherein some of the plurality of first through vias are arranged adjacent to the plurality of first gate line contacts in the horizontal direction.

4. The memory device of claim 1, wherein each of the plurality of first dummy structures comprises a first dummy insulating layer penetrating the first gate stack.

5. The memory device of claim 1, wherein each of the plurality of first through vias comprises:
a first conductive plug; and
a first insulating liner surrounding sidewalls of the first conductive plug.

6. The memory device of claim 5, wherein the first insulating liner comprises:
a first extension portion surrounding the sidewalls of the first conductive plug; and
a plurality of first protrusions protruding from the first extension portion in the horizontal direction.

7. The memory device of claim 1, wherein the lower cell array stack further comprises a first bit line that is between the first vertical channel structure and the peripheral circuit stack and is electrically connected to the first vertical channel structure.

8. The memory device of claim 1, wherein the lower cell array stack further comprises a first common source line that is spaced apart from the peripheral circuit stack with the first vertical channel structure therebetween and is configured to supply a common source voltage or a ground voltage to the first vertical channel structure.

9. The memory device of claim 1, wherein each of the plurality of first gate line contacts comprises:
a first gate contact plug; and
a first gate insulating spacer surrounding sidewalls of the first gate contact plug.

10. The memory device of claim 1, wherein the plurality of first gate lines extend in parallel with each other in the horizontal direction and overlap each other in the vertical direction.

11. The memory device of claim 1, further comprising:
a lower bonding structure being between the peripheral circuit stack and the lower cell array stack, the lower bonding structure configured to bond the peripheral circuit stack to the lower cell array stack.

12. A memory device comprising:
a peripheral circuit stack comprising a circuit substrate and a plurality of circuits thereon;
a first gate stack on the peripheral circuit stack, the first gate stack comprising a plurality of first gate lines stacked in a vertical direction;
a first vertical channel structure penetrating the first gate stack;
a plurality of first gate line contacts penetrating at least a portion of the first gate stack, the plurality of first gate line contacts being apart from each other on the circuit substrate in a first horizontal direction and a second horizontal direction, the second horizontal direction being perpendicular to the first horizontal direction, each of the plurality of first gate line contacts electrically connected to any one first gate line selected from among the plurality of first gate lines;
a plurality of first dummy structures adjacent to a periphery of the plurality of first gate line contacts, the plurality of first dummy structures spaced apart from each other in the first horizontal direction and the second horizontal direction, the plurality of first dummy structures penetrating the first gate stack;
a plurality of first through vias each being apart from a corresponding one of the plurality of first gate line contacts adjacent thereto in a third horizontal direction, the third horizontal direction crossing the first horizontal direction and the second horizontal direction, the plurality of first through vias penetrating the first gate stack, each of the plurality of first through vias connected to any one of the plurality of circuits of the peripheral circuit stack by penetrating the first gate stack; and
a lower cell array stack comprising a first wiring structure that electrically connects at least any one of the plurality of first through vias to a corresponding one of the plurality of first gate line contacts,
wherein a distance between a select one of the plurality of first gate line contacts and one of the plurality of first through vias adjacent thereto in the horizontal direction is greater than a distance between the select one of the plurality of first gate line contacts and one of the plurality of first dummy structures adjacent thereto in the horizontal direction.

13. The memory device of claim 12, wherein the plurality of first gate line contacts are in a collinear fashion in the first horizontal direction and the second horizontal direction.

14. The memory device of claim 12, wherein the plurality of first gate line contacts are in a zigzag form in the second horizontal direction and in a collinear fashion in the first horizontal direction.

15. The memory device of claim 12, wherein some of the plurality of first through vias are adjacent to the plurality of first gate line contacts in the third horizontal direction.

16. The memory device of claim 12, wherein each of the plurality of first dummy structures comprises a first dummy insulating layer penetrating the first gate stack.

17. A memory device comprising:
a peripheral circuit stack comprising a circuit substrate and a plurality of circuits thereon;
a lower cell array stack on the peripheral circuit stack; and
an upper cell array stack on the lower cell array stack,
wherein the lower cell array stack comprises
a first gate stack on the peripheral circuit stack, the first gate stack comprising a plurality of first gate lines stacked in a vertical direction,
a first vertical channel structure penetrating the first gate stack,
a plurality of first gate line contacts each penetrating at least a portion of the first gate stack,
a plurality of first dummy structures penetrating the first gate stack, each of the plurality of first dummy structures being adjacent to a corresponding one of the plurality of first gate line contacts adjacent thereto in a horizontal direction,
a plurality of first through vias penetrating the first gate stack, each of the plurality of first through vias being apart from a corresponding one of the plurality of first gate line contacts adjacent thereto in the horizontal direction, each of the plurality of first through vias connected to any one of the plurality of circuits of the peripheral circuit, and
a first wiring structure electrically connecting at least any one of the plurality of first through vias to a corresponding one of the plurality of first gate line contacts,
a distance between a select one of the plurality of first gate line contacts and a corresponding one of the plurality of first through vias adjacent thereto in the horizontal direction is greater than a distance between the select one of the plurality of first gate line contacts and a corresponding one of the plurality of first dummy structures adjacent thereto in the horizontal direction,
the upper cell array stack comprises
a second gate stack comprising a plurality of second gate lines that are stacked in the vertical direction,
a second vertical channel structure penetrating the second gate stack,
a plurality of second gate line contacts each penetrating at least a portion of the second gate stack,
a plurality of second dummy structures penetrating the second gate stack, each of the plurality of second dummy structures being adjacent to a corresponding one of the plurality of second gate line contacts adjacent thereto in the horizontal direction,
a plurality of second through vias penetrating the second gate stack, each of the plurality of second through vias being spaced apart from a corresponding one of the plurality of second gate line contacts adjacent thereto in the horizontal direction, and
a second wiring structure electrically connecting at least any one of the plurality of second through vias to a corresponding one of the plurality of second gate line contacts, and
a distance between a select one of the plurality of second gate line contacts and a corresponding one of the plurality of second through vias adjacent thereto in the horizontal direction is greater than a distance between the select one of the plurality of second gate line contacts and a corresponding one of the plurality of second dummy structures adjacent thereto in the horizontal direction.

18. The memory device of claim 17, wherein
the first wiring structure and the second wiring structure are electrically connected to any one of the plurality of first through vias, and
the first wiring structure and the second wiring structure are configured to receive a voltage from any one of the plurality of circuits of the peripheral circuit stack.

19. The memory device of claim 17, wherein
some of the plurality of first through vias are adjacent to corresponding ones of the plurality of first gate line contacts in the horizontal direction, respectively, and
some of the plurality of second through vias are adjacent to corresponding ones of the plurality of second gate line contacts in the horizontal direction, respectively.

20. The memory device of claim 17, wherein
each of the plurality of first dummy structures comprises a first dummy insulating layer penetrating the first gate stack, and
each of the plurality of second dummy structures comprises a second dummy insulating layer penetrating the second gate stack.
